(19) United States
(12) Patent Application Publication
(10) Pub. No.: US 2026/0237343 A1
(43) Pub. Date: Aug. 13, 2026

(54) METHOD OF DRIVING A DISPLAY DEVICE COMPRISING A VARIABLE-WAVELENGTH LED

(71) Applicant: PORO TECHNOLOGIES LTD, Cambridge, Cambridgeshire (GB)

(72) Inventor: Edward BUCKLEY, Cambridge (GB)

(73) Assignee: PORO TECHNOLOGIES LTD, Cambridge, Cambridgeshire (GB)

(21) Appl. No.: 19/152,687

(22) PCT Filed: Feb. 1, 2024
(86) PCT No.: PCT/GB2024/050284

§ 371 Date: Jul. 31, 2025

(30) Foreign Application Priority Data
Feb. 1, 2023 (GB) 2301476.4
Jun. 27, 2023 (GB) 2309690.2

(51) Int. Cl. G09G 3/32; H10H 20/812; H10H 20/825

(52) U.S. Cl. CPC G09G 3/32; G09G 2300/0452; G09G 2320/0626; G09G 2320/0666; H10H 20/812; H10H 20/825

(57) ABSTRACT

A method of driving a display device is provided, the display device comprising a variable-wavelength LED, in which the variable-wavelength LED is a pixel of the device, or one of a plurality of subpixels of a device pixel. The display device is programmed to operate using a palette of N available primary emission wavelengths λ_{P}, wherein each of the N available primaries is a wavelength emittable by the variable-wavelength LED, and the variable-wavelength LED is driveable to emit light at any of the N available primary emission wavelengths within an emission wavelength range of the variable-wavelength LED in response to N respective subfields of driving conditions. The method comprising the steps of: identifying an output signal to be displayed by a pixel, or a subpixel, of the display device, the output signal having an output chromaticity and output luminance L_{O}; and selecting a set of the N available primary emission wavelengths which are combinable to form the output signal. The set of selected primary emission wavelengths comprise a longest primary emission wavelength and one or more shorter primary emission wavelengths having wavelengths shorter than the longest primary emission wavelength. Each of the selected primary emission wavelengths are driven by a subfield of driving conditions with a respective duty cycle. The method comprises the steps of, in response to an image-adjustment signal, altering the wavelength of the longest selected primary emission wavelength, and altering the duty cycles of the driving conditions which drive the shorter primary emission wavelengths; and driving the variable-wavelength LED and optionally one or more separate LED subpixels of the display device to emit the selected primary emission wavelengths, so that the light emitted at the selected primary emission wavelengths forms an adjusted output signal.

The present invention relates to a method of driving a display device comprising a variable-wavelength LED. In particular, the invention relates to a method of adjusting the brightness and colour saturation of an output signal displayed by such a device.

### BACKGROUND

III-V semiconductor materials are of particular interest for semiconductor device design, in particular the family of III-nitride semiconductor materials.

“III-V” semiconductors include binary, ternary and quaternary alloys of Group III elements, such as Ga, Al and In, with Group V elements, such as N, P, As and Sb, and are of great interest for a number of applications, including electronics and optoelectronics.

Of particular interest is the class of semiconductor materials known as “III-nitride” materials, which includes gallium nitride (GaN), indium nitride (InN) and aluminium nitride (AlN), along with their ternary and quaternary alloys. (Al, In) GaN is a term encompassing AlGaN, InGaN and GaN. III-nitride materials have not only achieved commercial success in solid-state lighting and power electronics, but also exhibit particular advantages for quantum light sources and light-matter interaction.

While a variety of III-nitride materials are commercially interesting, Gallium nitride (GaN) is widely regarded as one of the most important new semiconductor materials, and is of particular interest for a number of applications.

The present invention will be described primarily by reference to GaN and InGaN, but may advantageously be applicable to alternative III-nitride material combinations.

It is known that the introduction of pores into bulk III-nitrides, such as GaN can profoundly affect its material properties (optical, mechanical, electrical, and thermal, etc.). The possibility of tuning a wide range of material properties of GaN and III-nitride semiconductors by altering its porosity therefore makes porous GaN of great interest for optoelectronic applications.

In a significant improvement over conventional three-colour LED displays, Poro Technologies Ltd, the present applicant, has developed variable-wavelength LEDs formed from III-nitride semiconductor materials grown over a porous region of III-nitride material.

Instead of a conventional LED which emits at a single colour, these variable-wavelength LEDs can emit a broad spectrum of different emission wavelengths in response to varying the driving conditions provided to the variable-wavelength LED. These variable-wavelength LEDs, and their method of manufacture, are set out below.

As the peak emission-wavelength of such variable-wavelength LEDs can be tuned by varying the driving conditions, a single variable-wavelength LED can take the place of multiple “single-colour” subpixels. In particularly preferred embodiments, the same variable-wavelength LED can be tuned to emit any one of red, green or blue light by tuning the driving conditions provided to that LED. This means that a colour display can be formed from an array of variable-wavelength LEDs, with each variable-wavelength LED acting as a colour-variable pixel, or alternatively as a colour-variable subpixel in a subpixellated display.

The ability of variable-wavelength LEDs to emit such a broad range of emission wavelengths makes display driving and calibration processes significantly more complex than it would be for a conventional RGB subpixel display. The peak emission wavelength of the variable-wavelength LEDs is strongly dependent on the magnitude of the electrical driving signal provided to a given LED, and longer-wavelength emission colours require lower-magnitude driving currents/voltages which inherently produce a lower luminance. This presents a challenge for those situations where a high display brightness is desired.

### SUMMARY OF INVENTION

The present application relates to a method of driving a display device comprising a variable-wavelength light emitting diodes (LED). The method may advantageously be used to drive a display device comprising a plurality of such variable-wavelength LEDs, for example an array of such LEDs.

The invention is defined in the independent claims, to which reference should now be made. Preferred or advantageous features of the invention are defined in the appended sub-claims.

The present invention is preferably carried out with a display device comprising a plurality of variable-wavelength LEDs. In preferred embodiments, such display devices comprise an array of variable-wavelength LEDs, with each variable-wavelength LED forming a pixel of the display device.

An example of variable-wavelength LEDs usable in the present invention are known as dynamic-pixel-tuning (DPT®) variable-wavelength LEDs from Poro Technologies Ltd, which are described in detail below.

A continuum of different emission wavelengths across an emission wavelength range can be emitted directly from a variable-wavelength LED by varying the driving conditions (the magnitude of the driving current and/or driving voltage) supplied to that LED. In CIE xy colourspace, the variable-wavelength LED can emit any colour along a continuous curved line of wavelengths. The length and shape of the emittable-wavelengths line in CIE xy colourspace is determined by the LED composition and structure, as described below.

One way of controlling the wavelength of light emitted by a variable-wavelength LED would be to provide a continuously-variable driving current to the LED. When the display device receives a signal identifying the target colour to be displayed by a given variable-wavelength LED, the driving current to that pixel could then be delivered at whatever magnitude is required for the LED to emit a particular wavelength from its continuum of emittable wavelengths. Downsides of this approach, however, are the difficulty of precisely controlling the variable driving current at all times, and the limitation that the variable-wavelength LED could only display chromaticities which are on the continuous line of emission wavelengths directly-emittable by that LED.

An alternative approach to driving variable-wavelength LEDs is to choose a set of predetermined “primaries” (primary wavelengths) from the continuum of emission wavelengths which are emittable by the variable-wavelength LED. Instead of controlling the emission wavelength to any point across the entire range of emittable colours, a limited set of operating points can be created by selecting a plurality of N primary wavelengths from the range of emittable colours. Each of the N primaries is then used as a predetermined operating point for the variable-wavelength LED, and the N respective driving conditions required to generate those N primary wavelengths are programmed into a display device incorporating the variable-wavelength LED.

The N primary wavelengths which are selected from the LED's range of emittable wavelengths form a palette of N available primaries, so that at any time the variable-wavelength LED can be controlled to emit light at one of these N predetermined primary wavelengths. The N available primaries define a colour gamut of a plurality of displayable colours, as any colour within this gamut can be displayed by the variable-wavelength LED by mixing the available primary wavelengths.

When the display device receives a signal identifying the target colour to be displayed by a given variable-wavelength LED, the device can select, out of the palette of N available primaries, a smaller set of 2 or more primaries which are mixable to render the target colour. Which primaries are selected from the N available primaries will depend on the wavelength of the target colour to be displayed.

By driving the LED to emit light at only a plurality of “primary” wavelengths instead of any wavelength from the continuum of directly-emittable wavelengths, the display device can display additional chromaticities which are not directly-emittable by the variable-wavelength LED. Primary wavelengths can be mixed using colour-mixing techniques known for conventional displays, such that the overall colour observed by a viewer is a temporal and/or spatial combination of the emitted primaries, rather than a single colour which is emitted “directly” by a single variable-wavelength LED. Driving variable-wavelength LEDs to emit light at predetermined “primary” wavelengths may also advantageously simplify driving requirements, as instead of having to provide a continuously-variable driving current, the display device can be calibrated to deliver a more manageable set of N predetermined driving conditions which generate the N available primaries.

The number “N” of available primaries can be selected depending on the size of the colour gamut which is desired, and the desired complexity of the control system. The larger the number of N, the larger the displayable colour gamut, but the larger the number of required driving conditions and the more complex the control requirements. As the variable-wavelength LED can emit a continuous range of wavelengths, N can be selected to be any number up to infinity (N=infinity being equivalent to continuous driving to any point within the range of emittable wavelengths). N is preferably greater than 3, so that the displayable colour gamut is sufficiently large to render a wide range of colours. Particularly preferably N is greater than or equal to 4, or 5, or 6, to encompass a large colour gamut while keeping the control requirements relatively straightforward. Preferably N may be less than or equal to 8, or 10, or 12, to prevent the control requirements from becoming overly complex.

In a preferred embodiment of a display device, each variable-wavelength LED is a pixel of the device, and the display device is a field-sequential display. In this embodiment, the same variable-wavelength LED pixel is driven to emit a plurality of discrete primary emission wavelengths in sequential subframes, by driving the LED pixel with the discrete driving conditions which correspond to those primary wavelengths.

In a sequential-field display, the same variable-wavelength LED may be controlled to emit multiple discrete primary emission wavelengths one after the other, by supplying different driving conditions to the LED in sequential subframes of a display frame. In this way, the same variable-wavelength LED may be a pixel that emits a plurality of selected “primary emission wavelengths” one after another within the duration of a single display frame. During each individual subframe, only one primary emission wavelength is emitted by the pixel. Thanks to the persistence of vision of human observers, the primary wavelengths emitted during sequential subframes temporally-average, so that the resulting colour observed by a person viewing the display at a normal viewing distance is the mixture of the colours emitted during a display frame.

In a subpixellated display, different primary emission wavelengths can be emitted by separate subpixels. The subpixels may all be variable-wavelength LEDs, or some subpixels may be non-variable-wavelength LEDs.

The brightness, or greyscale, of the emitted light can be varied by shortening or lengthening the duty cycle (pulse width) of the driving current pulses supplied to the LEDs in the display, which varies the “on time” of the LEDs. In a field-sequential display, the maximum duty cycle is achieved when the driving current is supplied to a variable-wavelength LED for 100% of the duration of the display frame, or subframe, allocated to the colour being emitted. While controlling the magnitudes of the driving currents provided to the variable-wavelength LEDs determines the emitted wavelengths, to achieve variable display brightness the duty cycles of the pulses of driving current must also be variable, which adds an additional layer of complexity to device control.

In Poro Technologies Ltd's dynamic-pixel-tuning (DPT®) variable-wavelength LEDs, the peak emission wavelength of variable-wavelength LEDs is strongly dependent on the magnitude of the electrical driving signal provided to a given LED, and longer-wavelength emission colours require lower-magnitude driving currents/voltages which inherently produce a lower luminance. This presents a challenge for those situations where a high display brightness is desired, and also a challenge for colour-balance when naturally-bright shorter wavelengths must be mixed with naturally-dimmer longer wavelengths.

In a first aspect of the present invention there is provided a method of driving a display device comprising a variable-wavelength LED. The display device may be programmed to operate using a palette of N available primary emission wavelengths λ_{P}, wherein each of the N available primaries is a wavelength emittable by the variable-wavelength LED. The variable-wavelength LED is driveable to emit light at any of the N available primary emission wavelengths within an emission wavelength range of the variable-wavelength LED in response to N respective subfields of driving conditions. The wavelength emitted by the variable-wavelength LED depends on the driving conditions provided to the LED, for example the magnitude of the driving current supplied to the LED by a driving circuit.

A subfield of driving conditions may alternatively be termed a set of driving conditions, referring to a specific condition of driving current and voltage which causes an LED to emit a corresponding wavelength of light.

The variable-wavelength LED may be a pixel of the device, or one of a plurality of subpixels of a device pixel.

The method may comprise the steps of identifying an output signal to be displayed by the display device, the output signal having an output chromaticity and output luminance L_{O}, and selecting a set of the N available primary emission wavelengths which are combinable to form the output signal. The set of selected primary emission wavelengths comprises a longest primary emission wavelength and one or more shorter primary emission wavelengths having wavelengths shorter than the longest primary emission wavelength. The set of selected primaries may for example be a pair of primary emission wavelengths—one longer primary emission wavelength and one shorter primary emission wavelength—or a set of three primary emission wavelengths. Each of the selected primary emission wavelengths is emittable by supplying an LED with a subfield of driving conditions with a respective duty cycle.

The duty cycle of a subfield of driving conditions refers to the duration over which said driving condition is supplied to an LED (the “on time” of the LED), relative to the duration of a display frame, or a display subframe allocated to that subfield.

The method may comprise driving the variable-wavelength LED and optionally one or more separate LED subpixels of the display device to emit the selected primary emission wavelengths, so that the light emitted at the selected primary emission wavelengths forms the output signal.

The method may further comprise, in response to an image-adjustment signal, altering the wavelength of the longest primary emission wavelength in the set of selected primary emission wavelengths to become an adjusted longest primary emission wavelength. The method may also comprise altering the duty cycles of the driving conditions which drive the one or more shorter primary emission wavelengths. The duty cycles of the one or more shorter primary emission wavelengths may be adjusted to maintain a white-balance condition with the adjusted longest primary emission wavelength.

The method may then comprise driving the variable-wavelength LED and optionally one or more separate LED subpixels of the display device to emit the adjusted longest primary emission wavelength and the shorter primary emission wavelengths, so that the light emitted at the selected primary emission wavelengths forms an adjusted output signal.

Due to the persistence of vision of a human observer viewing the display device at a normal viewing distance, the observer will perceive all of the light emitted by the LED pixel or subpixel during the display frame averaging out to form the output signal. The perceived output chromaticity will be a temporal-average of the discrete primary emission wavelengths emitted during the display frame.

The method preferably comprises the step of altering the wavelength of the longest primary emission wavelength without altering the duty cycle of its driving condition.

The method may comprise the step of altering the duty cycles of the driving conditions which drive the shorter primary emission wavelengths without altering the wavelengths of the shorter primary emission wavelengths. Alternatively, the method may comprise the step of altering the wavelength(s) of the shorter primary emission wavelengths.

Luminance and wavelength are inversely correlated for variable-wavelength LEDs, with longer wavelengths being less bright than shorter wavelengths driven with the same duty cycle. Altering the wavelength of the longest primary emission wavelength without altering the duty cycle of its driving condition will therefore naturally alter the luminance of the longest primary emission wavelength in the set of selected primary emission wavelengths. In order to maintain a colour-balance, or brightness-balance, between the selected primary emission wavelengths, the duty cycles of the driving conditions which drive the one or more shorter primary emission wavelengths are altered. Altering these duty cycles will naturally alter the luminances of the light emitted at the shorter primary emission wavelengths in the set, by altering the “on time” which the LED spends emitting these shorter primary emission wavelengths.

The step of altering the wavelength of the longest primary emission wavelength may comprise replacing the longest primary emission wavelength with an alternative primary emission wavelength from the palette of N available primary emission wavelengths.

Following the step of altering the wavelength of the longest primary emission wavelength and altering the duty cycles of the driving conditions driving the shorter primary emission wavelengths, the light emitted at the adjusted primary emission wavelengths may form an output signal with an adjusted output chromaticity and an adjusted output luminance L_{O}.

In an exemplary embodiment, a set of three primaries is selected for use in a given display frame. In order to achieve a wide displayable colour gamut, the three primaries may be selected to be nominally red (R), green (G) and blue (B).

In one example embodiment, red, green and blue primary emission wavelengths may be selected to be 639 nm, 533 nm and 466 nm respectively.

As the different driving conditions which drive the variable-wavelength LED to emit different primary emission wavelengths inherently cause those primary emission wavelengths to be emitted with different luminances, it may be desirable to control the luminances of the different primaries so that the output signal is appropriately colour-balanced. If this were not done and each primary was driven with the same duty cycle, the blue primary would be emitted with a much higher brightness than the red primary, and the combined output signal would be weighted towards blue.

In order to tackle this, a white-balance condition may be selected so that the relative luminances of the three primary emission wavelengths can be set.

The primary emission wavelengths and their driving subfields may preferably be set so that the combined wavelengths and luminances of the primaries are complementary and sum to a standard illuminant white point, such as CIE standard illuminant point D65.

In order to make D65 white using the three primary wavelengths of 639 nm, 533 nm and 466 nm, the luminances of the red/green/blue primaries must be set in the ratio 1.6:3.6:1 respectively.

The low current density required to drive the variable-wavelength LED to emit red light at 639 nm means that the luminance of the red primary is the lowest of the three primaries. In order to maximise the luminance of the red primary, the duty cycle of the red driving subfield may be set to 100% duty cycle.

In order to meet the required white-balance ratio of 1.6:3.6:1, the duty cycles of the green and blue driving subfields must be reduced until the luminances of the green and blue primaries fulfil this ratio with the red luminance.

The low brightness of the longest-wavelength of the selected primary emission wavelengths (the red primary in this example) is therefore a limiting factor in the overall brightness of the output signal.

Using the method of the present invention, the overall brightness of the output signal may be increased by lowering the red primary emission wavelength. Instead of providing the driving condition which generates 639 nm emission, the red primary emission wavelength may be adjusted to a shorter wavelength by adjusting the driving current (the magnitude of the driving current or voltage, for example) and instead providing the driving condition which generates a shorter wavelength. The adjusted red primary emission may be made shorter than 639 nm by increasing the current density supplied to the variable-wavelength LED. This adjusted longest primary emission wavelength will thus inherently be emitted with a higher luminance if the duty cycle of the driving conditions remains the same. With the new higher luminance of the shortened red primary emission wavelength, the luminances of the other primaries (the green and blue primaries) can be increased to once again meet the white-balance ratio by lengthening the duty cycles of the green and blue driving subfields. This results in an overall output signal with significantly improved output luminance.

This method advantageously allows the brightness of the output signal to be traded off against the size of the colour gamut displayable using the display device.

The downside of reducing the wavelength of the longest primary emission wavelength is that some chromaticities can no longer be displayed using the set of primary emission wavelengths. For example if the output signal to be displayed requires a highly-saturated long-wavelength red output chromaticity, this would not be possible if the wavelength of the target output chromaticity is longer than the wavelength of the adjusted shorter-wavelength red primary.

Where high brightnesses are desirable, but the low luminances achievable at long wavelengths are a limiting factor for the overall brightness of the output signal, the present method may be used to shorten the wavelength of the longest primary emission wavelength, to increase the luminance of that primary emission wavelength. The luminances of the remaining primary emission wavelengths may then be increased to maintain white balance with the shortened first primary wavelength, leading to a brighter overall display.

The present method may advantageously increase the brightness (output luminance) of the display at the cost of reducing the size of the displayable colour gamut. This may be desirable in a number of display applications, for example outdoor use where high brightness much more important than colour saturation.

If a brighter display is desired, the red duty cycle can be set to be 100% at a shorter primary wavelength. If a more saturated red output signal is desired, but a dimmer display, the red duty cycle can be set to be 100% at a longer primary emission wavelength.

The image-adjustment signal may instruct the display to adjust the luminance of the output signal, in order to display a desired adjusted output luminance L_{O}. This may be desirable in scenarios where the luminance, or brightness, of the display is more important than the chromaticity. For example in bright outdoor settings, it may be desirable to increase the brightness of the display to improve visibility, even if this means the output chromaticity has to be adjusted so that it no longer matches the desired output chromaticity.

In response to an image-adjustment signal requesting increased luminance, the method may comprise adjusting the set of selected primary emission wavelengths by decreasing the wavelength of the longest primary emission wavelength, and increasing the duty cycles of the driving conditions driving the shorter primary emission wavelengths.

The wavelength of the longest primary emission wavelength may be decreased by replacing the longest primary emission wavelength with a shorter-wavelength primary emission wavelength from the palette of N available primary emission wavelengths.

In response to an image-adjustment signal requesting reduced luminance, the method may comprise adjusting the set of selected primary emission wavelengths by increasing the wavelength of the longest primary emission wavelength, and decreasing the duty cycles of the driving conditions driving the shorter primary emission wavelengths. The wavelength of the longest primary emission wavelength may be increased by replacing the longest primary emission wavelength with a longer-wavelength primary emission wavelength from the palette of N available primary emission wavelengths.

The N available primary emission wavelengths define a colour gamut of a plurality of displayable colours, all of which can be displayed by some combination of the available primaries. The selected primary emission wavelengths define a displayable area of the colour gamut which is displayable by mixing the selected primary emission wavelengths. The displayable area of the gamut which can be displayed by any given set of, for example two, three or four primary emission wavelengths, is a subset of the entire colour gamut available using the palette of N available primaries.

As the selected primary emission wavelengths define a displayable area of the colour gamut, the step of altering the wavelength of the longest primary emission wavelength adjusts the displayable area of the colour gamut. The displayable area of the gamut which can be displayed after the longest primary emission wavelength has been altered is defined as an adjusted displayable area of the colour gamut.

The image-adjustment-signal may be a luminance-adjustment signal instructing the device to adjust the output luminance L_{O} to reach an adjusted output luminance L_{O}′.

The output chromaticity is inside the displayable area of the colour gamut, but in some cases the step of altering the wavelength of the longest primary emission wavelength may have the result that the output chromaticity is outside the adjusted displayable area of the colour gamut. In this case, as the display has been instructed to provide a specific adjusted luminance, the output chromaticity may be altered in order to achieve the desired adjusted output luminance. Thus the method may comprise the step of adjusting the output chromaticity of the output signal to an adjusted output chromaticity which is inside the adjusted displayable area of the colour gamut. The adjusted output chromaticity is inside the adjusted displayable area of the colour gamut, so it is displayable using the adjusted set of selected primary emission wavelengths. However, it is no longer the output chromaticity which was supposed to be displayed—the accuracy of the chromaticity has been slightly sacrificed in order to achieve the required adjusted output luminance.

The method may thus comprise the step of decreasing the displayable area of the colour gamut in order to reach the adjusted output luminance L_{O}′.

The image-adjustment-signal may alternatively be a gamut-adjustment signal instructing the device to adjust the output chromaticity to reach an adjusted output chromaticity. In some scenarios, for example in low-light scenarios or virtual-reality scenarios where high brightness is not required, it is desirable for output chromaticities to be rendered as accurately as possible. In this case, it may be desirable to adjust the display to use a set of primary emission wavelengths which maximise the displayable area of the colour gamut, for accurate colour-rendering across the largest-possible range of colours. In order to achieve this, the longest primary wavelength may be made as long as possible, which reduces the output luminances.

In response to an image-adjustment signal requesting an increase in the displayable area of the colour gamut, the method may comprise adjusting the set of selected primary emission wavelengths by increasing the wavelength of the longest primary emission wavelength, and decreasing the duty cycles of the driving conditions driving the shorter primary emission wavelengths.

The adjusted output chromaticity may be outside the displayable area of the colour gamut, so that the displayable area of the colour gamut has to be enlarged to make the adjusted output chromaticity displayable. The method may comprise altering the wavelength of the longest primary emission wavelength so that the adjusted output chromaticity is inside the adjusted displayable area of the colour gamut.

The method may comprise the step of decreasing the output luminance L_{O} in order to increase the displayable area of the colour gamut.

The method may comprise the step of altering the duty cycles of the driving conditions driving the shorter primary emission wavelengths to maintain a white-balance condition with the altered wavelength of the longest primary emission wavelength. Maintaining a white-balance condition means that the relative luminances of the set of selected primary emission wavelengths are balanced so that the selected primaries can be combined to display white light.

The white balance-condition of the output signal may be maintained by controlling the luminances of the shorter primary emission wavelengths, so that both before and after the longest primary has been altered, the combined wavelengths and luminances of the selected primary emission wavelengths are complementary and sum to a standard illuminant white point. The standard illuminant point is preferably CIE standard illuminant point D65.

In a preferred embodiment, the variable-wavelength LED is a pixel of the display device, and the method comprises driving the variable-wavelength LED to emit the selected primary emission wavelengths in sequential subframes within a display frame.

In an alternative embodiment, the variable-wavelength LED is a device subpixel which is driven to emit the longest primary emission wavelength, and the one or more shorter primary emission wavelengths are provided by driving a second LED subpixel. The second LED subpixel may be another variable-wavelength LED, or a conventional monochrome LED.

The selected primary emission wavelengths may be varied between display frames. For example the output signal to be displayed by the pixel or subpixels may vary between display frames, so in order to display different output signals at different times, different sets of primary emission wavelengths may be selected for different display frames. The selected primary emission wavelengths are variable within the palette of N available primary emission wavelengths.

The method may comprise the step of selecting a pair of two primary emission wavelengths from the N available primary emission wavelengths, and driving the display device to emit light at the set of two selected primary emission wavelengths, so that the output signal is a combination of light emitted at the two selected primary emission wavelengths.

The method may comprise the step of selecting a set of two primary emission wavelengths for each display frame, the two selected primary emission wavelengths being combinable to display the output signal for each respective display frame.

Alternatively the method may comprise the step of selecting a set of three primary emission wavelengths from the N available primary emission wavelengths, and driving the display device to emit light at the three selected primary emission wavelengths, so that the output signal is a combination of light emitted at the three selected primary emission wavelengths.

The method may comprise the step of selecting a set of three primary wavelengths for each display frame, the three selected primary emission wavelengths being combinable to display the output signal for each respective display frame.

The step of identifying the output signal to be displayed may comprise receiving a signal indicating the output chromaticity and output luminance which is to be displayed by the pixel or subpixel during a display frame. The output signal may be part of image instructions provided to the display device which determine the output signals to be displayed by the pixels of the display device.

The step of identifying an output signal to be displayed by the pixel, or subpixel, of the display device during a display frame may comprise receiving an input signal identifying a target colour to be displayed.

The step of selecting the pair of two of the N available primary emission wavelengths which are combinable to form the output signal may comprise selecting a set of primary emission wavelengths which are combinable to produce a given output chromaticity. The display device may be programmed to select sets of primary emission wavelengths from a database which indexes output chromaticities to sets of primary emission wavelengths.

The method may comprise the step of selecting a set of primary wavelengths, from the N available primary emission wavelengths, which are combinable to form the output signal comprises consulting a database.

The method may be a method of adjusting brightness and colour saturation in a display device comprising a variable-wavelength LED.

The method may comprise the step of shortening the wavelength of the longest primary emission wavelength by between 10 nm and 65 nm, or between 20 nm and 50 nm.

The method may comprise the step of adjusting the duty cycles of the one or more shorter primary emission wavelengths comprises increasing the duty cycles by between 10% and 95%.

The duty cycle which drives the longest primary emission wavelength may be not adjusted when the wavelength of the longest primary emission wavelength is adjusted.

The longest primary emission wavelength may preferably be driven with a 100% duty cycle.

The method may comprise the steps of: driving the variable-wavelength LED with a first subfield of driving conditions for a first duty cycle to emit a first primary emission wavelength λ_{P1} of the device, with a first luminance L₁; and driving the variable-wavelength LED, or a separate LED subpixel of the display device, with a second subfield of driving conditions for a second duty cycle to emit a second primary emission wavelength λ_{P2} of the device, with a second luminance L₂. The light emitted at the first and second primary emission wavelengths combines to form an output signal with an output chromaticity and output luminance L_{O}.

The method may further comprise adjusting the first subfield of driving conditions to adjust the wavelength of the first primary emission wavelength λ_{P1} to an adjusted first primary wavelength λ_{P1}′, so that driving the variable-wavelength LED to emit the adjusted first primary wavelength λ_{P1}′ for the first duty cycle results in an adjusted first luminance L₁′. As emission wavelength and luminance are interlinked for variable-wavelength LEDs, with the first duty cycle remaining the same, this change of emission wavelength creates a change in the luminance of the light emitted.

The method may comprise the further step of adjusting the second duty cycle to control the second luminance L₂, to maintain the white-balance of the output signal.

Although a continuum of different emission wavelengths are achievable by directly driving a variable-wavelength LED to emit a desired wavelength, additional chromaticities may be displayed by driving the LED to emit a plurality of “primary” wavelengths, such that the overall output signal observed by a viewer is a temporal combination of the emitted primaries.

In a subpixellated display, different primary emission wavelengths can be emitted by separate subpixels. The subpixels may all be variable-wavelength LEDs, or some subpixels may be non-variable LEDs.

In a sequential-field display, the same variable-wavelength LED may be controlled to emit all of the selected primary emission wavelengths, by supplying different driving subfields to the LED in sequential subframes of a display frame. In this way, the same variable-wavelength LED may be a pixel that emits all primaries one after another within the duration of a single display frame.

In one preferred embodiment, a set of two primaries (primary emission wavelengths and their associated subfields of driving conditions) may be selected. The output signal then has an output chromaticity and output luminance L_{O} that are the combination of the first and second primary emission wavelengths and their associated luminances.

In a preferred embodiment, a set of three primaries (primary emission wavelengths and their associated subfields of driving conditions) may be selected: the first primary emission wavelength, the second primary emission wavelength, and a third primary emission wavelength.

The method may comprise the step of selecting different primary emission wavelengths in different display frames. The most suitable primaries may be selected depending on the desired output signal for each display frame.

Maintaining the white balance of the output signal may comprise controlling the luminances of the first and second primary emission wavelengths λ_{P1}, λ_{P2}, so that the combined wavelengths and luminances are complementary and sum to a standard illuminant white point.

The standard illuminant white point may be CIE standard illuminant point D65.

The second duty cycle may be adjusted to control the second luminance L₂ without adjusting the second primary emission wavelength λ_{P2}.

The method may be a method of adjusting brightness and colour saturation in a display device comprising a variable-wavelength LED.

The method may comprise the step of driving the display device to emit light at a set of two primary emission wavelengths, so that the output signal is a combination of light emitted at the first and second primary emission wavelengths λ_{P1}, λ_{P2}.

The method may comprise the step of selecting the set of two primary wavelengths for each display frame.

The method may comprise the step of driving the display device to emit light at a set of three primary emission wavelengths, so that the output signal is a combination of light emitted at three discrete primary emission wavelengths: the first and second primary emission wavelengths λ_{P1}, λ_{P2}, and a third primary emission wavelength λ_{P3}.

The method may comprise the step of selecting the set of three primary wavelengths for each display frame.

The method may comprise the step of selecting different sets of primary wavelengths for emission in different display frames.

The first primary emission wavelength λ_{P1} may preferably be the longest of the primary emission wavelengths λ_{P} of the device. The first duty cycle of the driving subfield which produces the longest primary emission wavelength is preferably longer than the second duty cycle, and longer than the duty cycle driving any shorter-wavelength primaries.

The second primary emission wavelength λ_{P2} may be shorter than the first primary emission wavelength λ_{P1}, and the second duty cycle may be shorter than the first duty cycle.

The method may comprise the step of, when the output luminance L_{O} is below a threshold minimum luminance, shortening the wavelength of the first primary emission wavelength λ_{P1} to increase the first luminance L₁, and increasing the second duty cycle to increase the second luminance L₂ of the second primary emission wavelength and maintain the white-balance of the output.

The method may comprise the step of, when the output luminance L_{O} is below a threshold luminance, increasing the output luminance L_{O} by shortening the wavelength of the first primary emission wavelength λ_{P1} so that λ_{P1}′<λ_{P1} and the first duty cycle produces an increased first luminance such that L₁′>L₁, in which the step of adjusting the second duty cycle comprises increasing the second duty cycle to increase the second luminance L₂.

The method may comprise the step of shortening the wavelength of the first primary emission wavelength λ_{P1} by between 10 nm and 65 nm, or between 20 nm and 50 nm.

The step of adjusting the second duty cycle may comprise increasing the second duty cycle by between 10% and 95%.

The method may comprise the step of, in response to an input signal, lengthening the wavelength of the first primary emission wavelength λ_{P1} so that λ_{P1}′>λ_{P1} and the first duty cycle produces a reduced first luminance such that L₁′<L₁, in which the step of adjusting the second duty cycle comprises shortening the second duty cycle to reduce the second luminance L₂. In this situation, instead of sacrificing colour gamut to increase brightness, the opposite may be done, and brightness (output luminance) may be reduced while the first primary wavelength is increased. This may advantageously increase the size of the displayable colour gamut at the cost of lower output luminance, which may be desirable in a number of display applications, for example indoor use where little brightness is needed, but colour gamut is very important.

The input signal may be a signal to reduce output luminance L_{O} to increase the displayable color gamut.

The variable-wavelength LED may be configured to emit only the first primary emission wavelength λ_{P1}, and the second primary wavelength λ_{P2} may be provided by driving a second LED subpixel with the second subfield of driving conditions.

Alternatively, the variable-wavelength LED may be configured to emit two primary emission wavelengths within the emission range of the variable-wavelength LED, and the method may comprise driving the variable-wavelength LED in a field-sequential manner, in which the first and second subfields of driving conditions are supplied to the variable-wavelength LED in discrete sequential subframes of a display frame, so that the variable-wavelength LED emits the first primary emission wavelength λ_{P1} and the second primary emission wavelength λ_{P2} in respective subframes.

The method may comprise the step of driving the variable-wavelength LED, or a separate LED subpixel of the display device, with a third subfield of driving conditions for a third duty cycle to emit a third primary emission wavelength λ_{P3} of the device, with a third luminance L₃, so that the light emitted at the first, second and third primary emission wavelengths combines to form an output with an output chromaticity and output luminance L_{O};
adjusting the first subfield of driving conditions to adjust the wavelength of the first primary emission wavelength λ_{P1} to an adjusted first primary wavelength λ_{P1}′, so that driving the variable-wavelength LED to emit the adjusted first primary wavelength λ_{P1}′ for the first duty cycle results in an adjusted first luminance L₁′; and
adjusting the second and third duty cycles to control the second and third luminances L₂, L₃, to maintain the white balance of the combined output.

The third primary emission wavelength λ_{P3} may preferably be shorter than the first primary emission wavelength λ_{P1} and the third duty cycle is preferably shorter than the first duty cycle.

The method may comprise the step of, when the output luminance L_{O} is below a threshold luminance, increasing the output luminance L_{O} by shortening the wavelength of the first primary emission wavelength λ_{P1} so that λ_{P1}′<λ_{P1} and the first duty cycle produces an increased first luminance such that L₁′>L₁, in which the step of adjusting the second and third duty cycles comprises lengthening the second and third duty cycles to increase the second luminance L₂ and the third luminance L₃.

The method may comprise the step of, in response to an input signal, lengthening the wavelength of the first primary emission wavelength λ_{P1} so that λ_{P1}′>λ_{P1} and the first duty cycle produces a reduced first luminance such that L₁′<L₁, in which the step of adjusting the second and third duty cycles comprises shortening the second and third duty cycles to reduce the second luminance L₂ and the third luminance L₃.

The input signal may be a signal to reduce output luminance L_{O} to increase the displayable color gamut.

The variable-wavelength LED may be configured to emit only the first primary emission wavelength λ_{P1}. The second and third primary wavelengths λ_{P2}, λ_{P3} may be provided by driving a second variable-wavelength LED subpixel. Alternatively the second primary wavelength λ_{P2} may be provided by driving a second LED subpixel and the third primary wavelength λ_{P3} may be provided by driving a third LED subpixel.

The variable-wavelength LED may be configured to emit three primary emission wavelengths within the emission range of the variable-wavelength LED, and the method may comprise driving the variable-wavelength LED in a field-sequential manner, in which the first, second and third subfields of driving conditions are supplied to the variable-wavelength LED in discrete sequential subframes of a display frame, so that the variable-wavelength LED emits the first primary emission wavelength λ_{P1}, the second primary emission wavelength λ_{P2}, and the third primary emission wavelength λ_{P3} in respective subframes.

The first duty cycle may be a 100% duty cycle, such that the variable-wavelength LED is driven with the first subfield of driving conditions for the entire duration of a reference display frame or display subframe.

The first duty cycle is preferably not varied when the wavelength of the first primary emission wavelength λ_{P1} is varied.

The first duty cycle is preferably a 100% duty cycle.

In a preferred embodiment, the first primary emission wavelength λ_{P1} is a red (R) wavelength.

In a preferred embodiment, the first primary emission wavelength λ_{P1} and the adjusted first primary emission wavelength λ_{P1}′ are between 575 nm and 700 nm, or between 610 nm and 680 nm, preferably between 625 nm and 670 nm.

At least the first primary emission wavelength is emitted by the variable-wavelength LED. The one or more other primary emission wavelengths may be emitted by the same variable-wavelength LED, a separate variable-wavelength LED subpixel, or a standard single-wavelength LED subpixel.

The step of adjusting the first subfield of driving conditions to adjust the wavelength of the first primary emission wavelength λ_{P1} to an adjusted first primary wavelength λ_{P1}′ preferably comprises increasing the driving current provided to the variable-wavelength by the first subfield of driving conditions, and reducing the wavelength of the first primary emission wavelength. This in turn increases the first luminance emitted during the first duty cycle. The step of adjusting the second duty cycle to control the second luminance L₂ preferably comprises increasing, or lengthening, the second duty cycle to increase the second luminance.

The invention may provide a method of driving a display device comprising a variable-wavelength LED, the variable-wavelength LED being driveable to emit light at N emission wavelengths within an emission wavelength range of the variable-wavelength LED in response to N respective subfields of driving conditions, the method comprising the steps of:
driving the variable-wavelength LED with a first subfield of driving conditions for a first duty cycle to emit a first primary emission wavelength λ_{P1}, with a first luminance L₁;
driving the variable-wavelength LED with a second subfield of driving conditions for a second duty cycle to emit a second primary emission wavelength λ_{P2} of the device, with a second luminance L₂,
driving the variable-wavelength LED with a third subfield of driving conditions for a third duty cycle to emit a third primary emission wavelength λ_{P3} of the device, with a third luminance L₃,
so that the light emitted at the first, second and third primary emission wavelengths combines to form an output signal with an output chromaticity and output luminance L_{O};
adjusting the first subfield of driving conditions to adjust the wavelength of the first primary emission wavelength λ_{P1} to an adjusted first primary wavelength λ_{P1}′, so that driving the variable-wavelength LED to emit the adjusted first primary wavelength λ_{P1}′ for the first duty cycle results in an adjusted first luminance L₁′; and
adjusting the second duty cycle to control the second luminance L₂, and adjusting the third duty cycle to control the third luminance L₃ to maintain the white balance of the output signal.

The invention may provide a method of driving a display device comprising a variable-wavelength LED, the variable-wavelength LED being driveable to emit light at N emission wavelengths within an emission wavelength range of the variable-wavelength LED in response to N respective subfields of driving conditions, the method comprising the steps of:
driving the variable-wavelength LED with a first subfield of driving conditions for a first duty cycle to emit a red primary emission wavelength λ_{P1}, with a first luminance L₁;
driving the variable-wavelength LED with a second subfield of driving conditions for a second duty cycle to emit a green primary emission wavelength λ_{P2} of the device, with a second luminance L₂,
driving the variable-wavelength LED with a third subfield of driving conditions for a third duty cycle to emit a blue primary emission wavelength λ_{P3} of the device, with a third luminance L₃,
so that the light emitted at the first, second and third primary emission wavelengths combines to form an output signal with an output chromaticity and output luminance L_{O};
adjusting the first subfield of driving conditions to adjust the wavelength of the red primary emission wavelength λ_{P1} to an adjusted red primary wavelength λ_{P1}′, so that driving the variable-wavelength LED to emit the adjusted red primary wavelength λ_{P1}′ for the first duty cycle results in an adjusted first luminance L₁′; and
adjusting the second duty cycle to control the second luminance L₂, and adjusting the third duty cycle to control the third luminance L₃ to maintain the white balance of the output signal.

The variable-wavelength LED is preferably a microLED.

The variable-wavelength LED preferably has an emission wavelength range with a width of between 100 nm and 200 nm, or between 125 nm and 185 nm, or between 150 nm and 175 nm.

The emission wavelength range preferably extends from a lower limit, which is preferably below 500 nm or below 450 nm, to an upper limit, which is preferably above 595 nm or above 630 nm.

The lower limit of the emission wavelength range may preferably between 440 nm and 495 nm, or between 440 nm and 485 nm, preferably between 450 nm and 470 nm.

The upper limit of the emission wavelength range may preferably be between 595 nm and 700 nm, or between 610 nm and 680 nm, preferably between 625 nm and 670 nm.

The variable-wavelength LED may have a FWHM of 50 nm or less, or 40 nm or less, or 30 nm or less, or 20 nm or less.

The method may comprise the step of selecting first, second and third primary emission wavelengths.

The first, second and third primary emission wavelengths may be selected to be red (R), green (G) and blue (B) primary emission wavelengths respectively, and the three corresponding driving subfields may be such driving conditions as drive the variable-wavelength LED to emit R, G and B respectively.

In a preferred embodiment, the variable-wavelength LED is a device pixel, and the method is a field-sequential driving method for driving the variable-wavelength LED pixel to emit a plurality of primary emission wavelengths in sequential subframes of a display frame.

In a preferred embodiment, the variable-wavelength LED emits red light in response to the first driving subfield, green light in response to the second driving subfield, and blue light in response to the third driving subfield.

The first subfield may drive the variable-wavelength LED to emit a red primary emission wavelength, and the first duty cycle may have a duration of 100% of the duration of a display subframe, so that the first luminance L₁ is the luminance emitted at the red primary emission wavelength at 100% duty cycle.

The method may comprise the step of shortening the duty cycles of the green and blue subfields until the second and third luminances L₂, L₃ of the green and blue primary emission wavelengths fulfil a white-balance colour-mixing ratio with the red first luminance L₁.

The display device may be a field-sequential display, and the driving method may be a field-sequential driving method for driving a display device.

The variable-wavelength LED may be driven using field-sequential control to emit a plurality of discrete primary emission wavelengths in respective sequential subframes of a display frame.

The display device preferably comprises an array of variable-wavelength LEDs, each variable-wavelength LED in the array being individually driveable using the method of the present invention

The display device may be a subpixellated display device in which the variable-wavelength LED forms a subpixel configured to emit the first primary emission wavelength, and in which the device comprises one or more additional subpixels configured to emit other primary emission wavelengths.

In a second aspect the invention may provide a method of driving a display device comprising a variable-wavelength LED, the variable-wavelength LED being driveable to emit light at emission wavelengths within an emission wavelength range of the variable-wavelength LED in response to different electrical driving conditions supplied to the variable-wavelength LED, the method comprising the steps of:
adjusting the wavelength of a first primary of a set of two or more primaries, each primary having an associated wavelength and luminance, and
adjusting the luminance of the other primaries in the set of two or more primary wavelengths to maintain a white-balance condition with the adjusted first primary.

The step of adjusting the wavelength of the first primary preferably comprises adjusting the duty cycle of electrical driving conditions supplied to drive the first primary.

The step of adjusting the luminance of the other primaries preferably comprises adjusting the duty cycle of electrical driving conditions supplied to drive the other primaries.

The second aspect may have any of the features described above in relation to the first aspect of the invention.

### Opto-Electronic Display Device

The method of the present invention is preferably carried out on an opto-electronic display device comprising:
a driver wafer comprising a driver circuit; and
a pixel matrix formed by an array of variable-wavelength LEDs, each variable-wavelength LED being connected to the driver circuit and configured to receive a tunable driving signal.

Display devices which are driveable using the method of the present invention preferably have a display screen which is made up of an array of variable-wavelength LEDs. Each variable-wavelength LED acts as a pixel, so that the array of variable-wavelength LEDs forms a pixel matrix. Each pixel of the display is preferably a variable-wavelength LED which responds to different driving current densities, or different driving voltages, by emitting different peak emission wavelengths.

The driver circuit may be configured to control the power or the current or the voltage of the power supply to each variable-wavelength LED in the pixel matrix. The driver circuit may be configured to provide a pulsed, or CW, or quasi-CW power supply to the variable-wavelength LED device mesas.

Each variable-wavelength LED has an epitaxial structure which preferably comprises an n-doped region, a p-doped region, and a light-emitting region arranged between the n-doped region and the p-doped region.

Each variable-wavelength LED may comprise a porous region of III-nitride material epitaxially connected to the variable-wavelength LED epitaxial structure.

Particularly preferably, each variable-wavelength LED in the pixel matrix has the same device epitaxial structure. As the array of variable-wavelength LEDs may be formed by etching a single epitaxial structure into a plurality of separate LED device mesas, the composition and layer arrangement of each of the device mesas will be the same.

Although the epitaxial layer design of each variable-wavelength LED is the same, different LEDs may optionally have different lateral sizes, such that different variable-wavelength LEDs have light-emitting areas of different sizes.

Preferably each variable-wavelength LED in the pixel matrix is electrically coupled to its own CMOS driver in the driver circuit, such that each pixel (each variable-wavelength LED) is independently driveable by the driver circuit.

The LED epitaxial device structure of the variable-wavelength LEDs comprise a light-emitting region which preferably comprises a multiple quantum well (MQW) containing a plurality of quantum wells (QWs), or quantum dots, quantum wires, or other quantum nanostructures.

An LED comprises an n-doped portion, a p-doped portion, and a light-emitting region located between the n-doped portion and a p-doped portion, the light-emitting region comprising a light-emitting layer which emits light at a peak emission wavelength under electrical bias thereacross.

### Variable-Wavelength LEDs

In a particularly preferred embodiment, each variable-wavelength LED in the display has the same the variable-wavelength LED device epitaxial structure, such that each variable-wavelength LED in the display device is a separate variable-wavelength LED which is configured to emit a variable peak emission wavelength in response to variations in the driving current provided to that LED. By driving the variable-wavelength LED pixels separately through a driver circuit it is thus advantageously possible to tune the emission wavelength of each pixel individually by providing different driving currents to the variable-wavelength LED pixels.

The variable-wavelength LEDs are configured to emit a variable peak emission wavelength in response to variations in the electrical driving signal (variations in the driving current or driving voltage) provided to the LED. The peak emission wavelength of the LED is preferably continuously controllable over an emission wavelength range of at least 40 nm by varying the driving current to the LED. The peak emission wavelength may preferably be variable over an emission wavelength range of at least 50 nm, or at least 60 nm, or at least 70 nm, or at least 80 nm by varying the driving current, preferably over a range of up to 100 nm or 110 nm or 120 nm or 140 nm, or 160 nm, or 180 nm, or 200 nm, or 400 nm, or 450 nm.

The display is preferably connected to a driver circuit which is configured to supply a variable-magnitude driving current or a variable-magnitude driving voltage, to the variable-wavelength LED pixels, to vary the peak emission wavelength of the variable-wavelength LED device mesas.

A variable-wavelength light emitting diode (LED) driveable using the method of the present invention preferably comprises:
an n-doped portion;
a p-doped portion;
a light-emitting region located between the n-doped portion and a p-doped portion, the light-emitting region comprising a light-emitting layer which emits light at a peak emission wavelength under electrical bias thereacross;
wherein the LED is configured to receive a power supply, in which the peak emission wavelength of the LED is continuously controllable over an emission wavelength range by varying, or controlling, the power supply. The peak emission wavelength of the variable-wavelength LED is preferably continuously controllable, or continuously variable, over an emission wavelength range of at least 40 nm by varying, or controlling, the power supply.

As the peak emission wavelength of the variable-wavelength LED is preferably continuously controllable, or continuously variable, over an emission wavelength range the LED can be described as a variable-wavelength LED.

The variable-wavelength emission behaviour of the LED structure is enabled by the fact that the LED structure (the n-doped portion, the light-emitting region and the p-doped portion) are grown over a template containing a porous region. The present inventors have found that the presence of a porous region of III-nitride material in the template structure prior to overgrowth of the LED structure leads to higher quality crystal growth and thus significant benefits including the possibility of varying the emission wavelength of the LED light-emitting region. The mechanism by which the porous region enables the variable wavelength emission of the LED is the subject of ongoing study. Benefits provided to the LED by the porous region include strain relaxation, lattice parameter enlargement, wafer bow reduction, and mechanical and thermal influence during the light-emitting region being grown at high temperatures.

The variable-wavelength LED is configured to receive a supply of power, or a drive current, from a power supply or LED driver. The term “power supply” is used herein to refer to the power, or current, or voltage, supplied to drive an LED during use.

The peak emission wavelength of the LED may preferably be continuously controllable, or continuously variable, over an emission wavelength range by varying, or controlling, the magnitude of a drive current provided to the variable-wavelength LED.

In traditional LED devices, changes to the driving current provided to the LED produces a very small shift in emission wavelengths, but the present inventors have found that the wavelength shift can be broadened and controlled to a greater extent than traditional LED materials. Rather than the few nm emission range of prior art devices, the LED of the present invention is controllable to emit over a far broader emission range, for example a range of at least 40 nm. As the present LED is tunable to emit over a broad wavelength range, it may be referred to as a variable-wavelength LED.

The LED may be a dynamic colour-tunable LED, in which the peak emission wavelength of the LED is tunable by varying the driving conditions provided to the LED by the driving circuit.

The LED is preferably driveable to emit at a single peak emission wavelength in response to a stable power supply, but to emit at different peak emission wavelengths in response to variations in the power supply. Thus the LED may be used to emit a particular colour for a prolonged period, or alternatively the LED may be driven to emit a variety of different wavelengths by providing varying driving conditions.

Preferably, the n-doped portion, the p-doped portion and the light-emitting region all comprise or consist of III-nitride material, preferably GaN, InGaN, AlGaN or AlInGaN

The variable-wavelength LED preferably contains a single epitaxially-grown diode structure containing the n-doped portion, the p-doped portion and the light-emitting region. Thus the variable peak emission wavelengths of the LED are all emitted by the same LED diode structure and composition.

The LED preferably comprises a porous region of III-nitride material. The light-emitting region of the LED is preferably formed over a porous region of III-nitride material. In some embodiments, one of the n-doped portion or the p-doped portion may contain the porous region of III-nitride material. In other embodiments, the n-doped portion; the p-doped portion; and the light-emitting region are provided on a substrate which comprises the porous region of III-nitride material. During epitaxial growth of the LED, the light-emitting region is preferably overgrown after the porous region has been formed.

The present inventors have found that a porous region of III-nitride material enables the same LED to emit at a range of peak emission wavelengths, rather than at one specific wavelength. The peak emission wavelength of the LED may be varied across an emission wavelength range by varying the power supply provided to the LED. The present invention therefore provides a variable-wavelength LED, which may be controlled to emit at any wavelength across a continuous emission wavelength range. By varying the driving conditions provided to the LED by the power supply, the LED is capable of emitting at any wavelength within the emission wavelength range of said LED, and not simply at discrete peak emission wavelengths.

The present inventors have found that the ability of the LED to emit at tuneable wavelengths across a broad emission range may be imparted by either incorporating a porous region of III-nitride semiconductor material into the LED structure, or forming the LED diode structure over a porous region of III-nitride semiconductor material. Benefits provided to the LED by the porous region include strain relaxation, lattice parameter enlargement, wafer bow reduction, and beneficial mechanical and thermal influences during the growth of the light-emitting region at high temperatures.

The light-emitting region of the LED is preferably formed over a porous region of III-nitride material during manufacture, so that the porous region influences the structure and mechanical properties of layers of semiconductor that are epitaxially deposited over the porous region. Layers of semiconductor material that are deposited over the porous region during growth experience benefits such as strain reduction, lattice parameter enlargement, and wafer bow reduction, which are imparted to the LED light-emitting region and affect its structure and its light-emitting behaviour.

Once the LED light-emitting (active) region has been epitaxially grown over the porous region, and the quality of the active region has been enhanced by the influence of the porous region, the beneficial effects of the porous region on the emission properties are permanently imparted to the LED active region. Thus the LED diode structure may be retained on the porous region, in which case the variable-wavelength LED comprises a porous region of III-nitride material, or alternatively, during the processing of LEDs into devices after epitaxial growth, the porous region may be removed from the LED structure.

The width of the emission wavelength range may vary depending on the structure and composition of the LED structure (the n-doped portion, light-emitting region and p-doped portion), and on the structure and porosity of the porous region. The width of the emission wavelength range may also vary depending on the size and shape of the LED (the pixel size and shape).

In preferred embodiments, the peak emission wavelength is controllable over an emission wavelength range of at least 40 nm, or at least 50 nm, or at least 60 nm, or at least 70 nm, or at least 80 nm by varying the power supply. Preferably the peak emission wavelength is controllable over an emission wavelength range of up to 100 nm, or 110 nm, or 120 nm, or 130 nm, or 140 nm, or 150 nm, or 160 nm, or 170 nm, or 180 nm, or 190 nm, or 200 nm, or 400 nm, or 450 nm. The size of the emission wavelength range obtainable by the present LED is thus far greater than the emission ranges achievable with LEDs of the prior art.

The variable-wavelength LED is advantageously controllable to emit at any peak emission wavelength within its emission wavelength range. By varying the characteristics of the power supply and LED pixel size and shape, the variable-wavelength LED may therefore be controlled to emit light at any selected peak emission wavelength within this range.

The emission wavelength of the variable-wavelength LED is preferably continuously variable across its emission wavelength range in response to driving conditions provided by a power source being varied continuously across a range of driving conditions.

The position of the emission wavelength range in the electromagnetic spectrum may also vary depending on the design of the variable-wavelength LED structure (the n-doped portion, light-emitting region and p-doped portion). For example the wavelengths contained in the emission wavelength range may depend on the number and composition of light emitting layers in the variable-wavelength LED. A large variety of LED active regions are known in the art for emitting at different wavelengths in the visible spectrum, so by light-emitting region forming the LEDs of the present invention with different light-emitting regions, emission wavelength ranges covering different portions of the spectrum may be obtained.

The variable-wavelength LED emission wavelength range may be between 400 nm and 850 nm, or between 400 nm and 800 nm, or between 400 nm and 690 nm, or between 400 nm and 675 nm. The emission wavelength range may be a sub-range within the range of 400 nm to 750 nm. The emission wavelength range may be tuned to cover any part of this range by selecting different LED active regions and controlling the size and shape of the LED pixels.

Preferably the emission wavelength range of the variable-wavelength LED extends from a lower end below 410 nm, or 430 nm, or 450 nm, or 470 nm, or 500 nm, or 520 nm, or 540 nm, or 560 nm, to an upper end above 570 nm, or 580 nm, or 600 nm, or 610 nm, or 630 nm, or 650 nm, or 675 nm. The first and second ends of the emission wavelength range may be tuned depending on the selection of LED structure and LED shape and size, as described above.

For example in preferred embodiments the lower end of the emission wavelength may be between 400 nm and 450 nm (violet) or between 450 nm and 500 nm (blue) or between 500 nm and 570 nm (green), and the upper end of the emission wavelength may be between 570 nm and 590 nm (yellow), or between 590 nm and 610 nm (orange), or between 610 and 700 nm (red).

In a preferred embodiment, the variable-wavelength LED emission wavelength range may extend from a lower end that is below 500 nm to a higher end that is above 610 nm, so that the peak emission wavelength of the LED may be varied to emit at any wavelength from blue (below 500 nm) to red (above 610 nm) by varying the power supply. Providing a single LED design that can be controlled to emit at blue wavelengths (450-500 nm), green (500-570 nm) and also at yellow (570-590 nm), orange (590-610 nm) and red (610-760 nm) is highly advantageous, and could provide significant advantages for LED displays.

In other preferred embodiments, the variable-wavelength LED emission wavelength range may extend between 520 nm and 660 nm, or between 550 nm and 650 nm, by varying the power supply to the LED.

In a particularly preferred embodiment, the peak emission wavelength is controllable between 540 nm and 680 nm, or between 560 nm and 675 nm, by varying the power supply. Thus, the same LED may be controllable to emit at a peak emission wavelength anywhere between 540 nm in the green and 680 nm in the red. Green and red LEDs have historically been more difficult to manufacture than shorter wavelength blue LEDs due to issues such as the difficulty of incorporating the required indium content into the light-emitting region. Providing a single LED design that can be controlled to emit at green wavelengths (500-570 nm) and also at yellow (570-590 nm), orange (590-610 nm) and red (610-760 nm) is therefore highly advantageous, and could provide significant advantages for LED displays.

In another preferred embodiment, the peak emission wavelength is controllable between 520 nm and 675 nm, or between 550 nm and 650 nm, by varying the power supply.

Although the variable-wavelength LED can emit across a continuous emission wavelength range, in some embodiments it may be desirable to control the LED to function in a plurality of discrete emission modes, for example in response to a power supply having a plurality of driving modes. For example by driving the LED in a plurality of different modes corresponding to discrete emission colours, a simplified colour display may be provided, in which discrete emission colours are mixed in known methods to give a desired visual effect.

The variable-wavelength LED is preferably controllable to emit at least two discrete peak emission wavelengths by varying the driving conditions provided by the power supply between two discrete driving conditions (such as two discrete magnitudes of drive current). The LED may be controllable to emit at a first peak emission wavelength in response to a first driving condition provided by the power supply (which may be a drive current having a first magnitude), at a second peak emission wavelength in response to a second driving condition provided by the power supply (which may be a drive current having a second magnitude different from the first magnitude).

The variable-wavelength LED is preferably controllable to emit at least three discrete peak emission wavelengths by varying the driving conditions provided by the power supply. The peak emission wavelength of the variable-wavelength LED may thus be variable over at least three “colours” in the EM spectrum.

The variable-wavelength LED may be controllable to emit at a first peak emission wavelength in response to a first driving condition provided by the power supply, at a second peak emission wavelength in response to a second driving condition provided by the power supply, and at a third peak emission wavelength in response to a third driving condition provided by the power supply.

The variable-wavelength LED may preferably be controllable to emit a blue peak emission wavelength in response to a first driving condition provided by the power supply, to emit a green peak emission wavelength in response to a second driving condition provided by the power supply, and to emit a red peak emission wavelength in response to a third driving condition provided by the power supply.

The variable-wavelength LED may be controllable to emit a first peak emission wavelength in the range 400-500 nm in response to a first driving condition provided by the power supply, to emit a second peak emission wavelength in the range 500-550 nm in response to a second driving condition provided by the power supply, and to emit a third peak emission wavelength greater than 600 nm in response to a third driving condition provided by the power supply.

Preferably, the variable-wavelength LED is controllable to emit a first peak emission wavelength in the range 430-460 nm in response to a first driving condition provided by the power supply, to emit a second peak emission wavelength in the range 510-560 nm in response to a second driving condition provided by the power supply, and to emit a third peak emission wavelength in the range 600-660 nm in response to a third driving condition provided by the power supply.

The first, second and third driving conditions may be first, second and third current densities, or the first, second and third driving conditions may be first, second and third power densities.

The morphology of quantum wells (QWs) in the active light-emitting region may be varied. For example the light-emitting region may contain uniform QWs with well-defined interfaces or fragmented QWs with less well-defined interfaces, fragmentation, or QW well width/composition fluctuation or quantum dots like localisation centres. This control of QW morphology can determine the range of the variable emission wavelength to be controlled and manipulated.

The light-emitting region preferably comprises a plurality of quantum wells (QWs). The quantum wells may be continuous. The quantum wells may be fragmented, or discontinuous.

The variable-wavelength LED may comprise a current constraining layer, or a current limiting layer, which is a dielectric layer configured to confine the lateral area of the LED through which current is conducted. The use of a current constraining layer may advantageously allow further control of the current density, in order to better control the peak emission wavelength of the LED.

The current constraining layer may advantageously enable the manipulation of the power density provided to the variable-wavelength LED, in order to control the peak emission wavelength.

The current constraining layer is preferably a layer of dielectric material. For example, the current constraining layer may be any dielectric, for example SiO₂, SiN or SiNx.

The current constraining layer may be positioned in a variety of positions in the variable-wavelength LED, as long as it confines the lateral area of the LED through which current is conducted. The current constraining layer may be positioned in the LED between an electrical n-contact and an electrical p-contact.

The current constraining layer may be positioned adjacent to either the n-doped portion or the p-doped portion of the LED. For example the current constraining layer may be positioned between the n-doped portion and the light-emitting region. Alternatively the current constraining layer may be positioned between the light-emitting region and the p-doped portion. The current constraining layer may be positioned between an electrical contact and the LED structure (n-doped portion, p-doped portion and light-emitting region).

The current constraining layer preferably comprises an aperture extending through the current constraining layer, or one or more apertures extending through the current constraining layer. The aperture may preferably be positioned in the centre of the current constraining layer. For example the current constraining layer may comprise a circular opening in the centre of the LED structure.

The variable-wavelength LED may be configured so that an electrical contact is in contact with the LED structure via the aperture in the current constraining layer, so that the area of the aperture defines a contact area over which the contact and the LED structure are touching.

The lateral dimensions of the or each aperture is preferably much smaller than the lateral dimensions of the LED. By providing an aperture through the dielectric current constraining layer, high local current density may be achieved, which may advantageously enable improved control of the power through the LED.

For example the lateral width (or diameter) of the aperture may be equal to or less than 50% of the lateral width of the LED structure (the LED mesa). The width of the aperture may be equal to or less than 45%, or 40%, or 35%, or 30%, or 25%, or 20% of the width of the LED structure.

The relative area of the aperture compared to the overall area of the current constraining layer (the blocked region) may be varied to modify the local current density.

The light emitting region preferably comprises a multiple quantum well (MQW) containing a plurality of quantum wells (QWs), or quantum dots, quantum wires, or other quantum nanostructures.

In some embodiments, the light-emitting region comprises a plurality of quantum wells (QWs), and the quantum wells are continuous.

The present inventors have found that non-uniformities in the light-emitting region have a significant effect in broadening the emission wavelength range across which a light-emitting region can emit light in response to variations in the power supplied to the LED. In the prior art, non-uniformities in the light-emitting region are typically considered problematic flaws, which are unwanted and should be avoided in any way possible because the goal is typically a high-quality, low-flaw semiconductor wafer. The present inventors have eschewed this prejudice in the art, and found that intentionally creating non-uniformities in the light emitting region may advantageously broaden the emission wavelength range and result in a variable-wavelength LED which can emit over a far broader wavelength range than has ever been possible in the prior art.

In alternative embodiments of the present invention, the light-emitting region is non-uniform, fragmented, or discontinuous. The light-emitting region may be deliberately introduced to achieve the effect of carrier localisation centres in InGaN quantum wells, such as multiple types of QW region with different Indium composition and well width and quantum barriers, non-uniform, or fragmented, or broken, or gappy, or discontinuous quantum wells which would result in fluctuation in the well width, InGaN quantum dots or nanostructures, quantum wells formed on polar, semi-polar or non-polar facets.

In a preferred embodiment, the light-emitting region comprises a plurality of quantum wells (QWs), and the quantum wells are non-uniform, fragmented, or discontinuous.

The plurality of QWs may comprise fluctuations in well-width. For example the well width of the QWs may fluctuate by at least 2%, 5%, 10%, 20%, 25%, or 50%, or 75%. The well width fluctuations can be variations between quantum wells (vertical direction) as well as within one quantum well (lateral direction).

The plurality of QWs may comprise fluctuations in alloy composition. For example the indium composition of the QWs may vary by at least 2%, 5%, 10%, 20%, 25% or 50% or 75% across the light-emitting region.

The inventors have found that fluctuations in well-width and/or alloy composition may induce carrier localisation centres, either in the upper interface or lower interface of the QWs. Any carrier localisation centres would induce the variable wavelength in the variable-wavelength LED of the present invention. The larger the density of those carrier localisation centres, the larger the variable wavelength range can be achieved.

The variable-wavelength LED may comprise a v-shaped pit which extends, or propagates, through the light emitting active region. Preferably the LED comprises a plurality of v-shaped pits which extend through the light-emitting region.

Preferably the variable-wavelength LED may comprise a density of v-shaped pits (measured looking down onto the LED structure from above) of at least 1×10⁷/cm², for example at least 5×10⁷/cm² or at least 1×10⁸/cm², for example a density of v-shaped pits of 1×10⁷/cm² to 5×10⁹/cm².

The variable-wavelength LED may comprise a density of v-shaped pits of less than 5×10⁹/cm², for example a density of v-shaped pits of less than 1×10⁹/cm² or less than 5×10⁸/cm².

V-shaped pits are a phenomenon known in the art of epitaxial semiconductor growth, and methods of growing v-shaped pits in semiconductor structures are known in the art. For example, v-shaped pits and their growth are described in the prior art in The effect of nanometre-scale V-pits on electronic and optical properties and efficiency droop of GaN-based green light-emitting Diodes; Zhou et al; Scientific Reports |(2018) 8:11053| DOI:10.1038/s41598-018-29440-4.

These v-shaped pits are v-shaped when viewed in cross-section, but in reality form as conical or funnel-shaped voids in semiconductor structures that are grown from the bottom up using conventional epitaxial growth methods. While the cross-section of the pits is v-shaped, the pits are typically hexagonal when viewed from above. The point of the v-shaped pits are always directed downwards towards earlier-deposited layers of semiconductor structure, as the pits widen as subsequent layers of epitaxial growth are deposited on top of the structure.

Although v-shaped pits are known in the art, they are typically considered a problematic flaw in semiconductor structures, which are unwanted because the goal is typically a high-quality, low-flaw semiconductor wafer.

In the unusual situations where v-shaped pits have been incorporated into semiconductor structures in the past, the v-shaped pits have been used as a screening mechanism to create higher band gap regions which prevent current carriers going down threading dislocations as a leakage path.

In some preferred embodiments of the present invention, however, v-shaped pits are intentionally incorporated into the variable-wavelength LED structure. The v-shaped pits extend far enough down into the semiconductor structure that they terminate in a layer below the active light-emitting region. This means that the v-shaped pits must extend through the thickness of the active light-emitting region.

The present inventors have found that v-shaped pits extending through the light-emitting region of the LED structure may advantageously broaden the emission wavelength range over which a variable-wavelength LED can emit.

As the v-shaped pits extend through the active region of the LED, during epitaxial growth from the bottom up, quantum well (QW) layers that are planar across the rest of the structure are grown on the sloping side walls of the v-shaped pits. The QWs deposited on the pit sidewalls are distorted and stretched around the sides of the pits, so end up being of different thickness and composition compared to the planar QWs across the bulk of the structure.

Around the v-shaped pits, QW layers of semiconductor material are grown as flat planar layers. The active light-emitting region is thus planar around the v-shaped pit. In the location of the v-shaped pits, however, the active layers are distorted and stretched downwards along the sidewalls into the v-shaped pit. This stretching effect changes the thickness of the QWs on the sidewalls of the pit, so that they are different in thickness compared to the planar QW layers formed over the rest of the LED structure.

The inventors have found that v-shaped pits can create local strain relaxation, and MQWs deposited on the sidewall of these v-pits will have different thickness and composition compared to the rest of the MQW, hence the MQW in the region of the v-shaped pits will produce a different emission wavelength.

The quantum wells grown on the side walls of the v-shaped pit are thinner than the bulk planar QWs elsewhere in the structure, which may affect the QW bandgap and allow the QWs in this region to emit at wavelengths different from those emitted by the planar QWs elsewhere in the structure. In addition to this, the QWs on the pit sidewalls may end up having a higher indium (In) content than the surrounding planar QWs, because the sidewalls expose a semipolar facet of the QWs—this facet incorporates more indium during epitaxial growth, so the QWs in the region of the v-shaped pits may be higher in indium than the planar QWs around the pits. Higher indium incorporation typically leads to longer peak emission wavelengths. Both the QW thickness and the indium content affect the emission wavelengths produced by the light-emitting region. The presence of v-shaped pits in the LED structure may thus advantageously modify the composition and thickness of QWs in the light-emitting region in a way that expands the emission wavelength range over which the LED can be driven to emit light.

V-shaped pits typically grow from threading dislocations in the semiconductor structure. The threading dislocations are perpetuated upwards through the structure as additional layers are grown over layers containing a threading dislocation, and at a certain point the dislocation widens into a v-shaped pit. Typically the skilled person aims to keep threading dislocation concentrations low in order to produce a “high quality” low-flaw wafer.

V-shaped pits can alternatively be grown using 3-dimensional epitaxial growth modes. 3D epitaxial deposition techniques are known in the art and are typically used to grow “islands” or “pyramids” of semiconductor material on a template. By controlling deposition of the LED structure using 3D epitaxial deposition techniques, v-shaped pits can be artificially grown in desired locations, with no need for a threading dislocation to be present to “seed” the formation of the v-shaped pit. By using this deposition control, the bottom (nadir) of the pit may be created at a desired location in the structure-both a desired lateral position and a desired height in the structure, for example in a particular layer of the semiconductor structure below the active light-emitting region.

The bottom of the v-shaped pit may be located in the connecting layer of the semiconductor structure. The connecting layer may be positioned between the porous region and the n-doped portion.

The bottom of the v-shaped pit may be located in a pre-strain layer of the semiconductor structure. The pre-strain layer may be positioned above the n-doped portion and below the light-emitting region.

Preferably the variable-wavelength LED comprises a plurality of v-shaped pits which extend through the active light-emitting region.

Preferably the variable-wavelength LED comprises a density of v-shaped pits (measured looking down onto the LED structure from above) of at least 1×10⁷/cm², for example at least 5×10⁷/cm² or at least 1×10⁸/cm². The LED may comprise a density of v-shaped pits of less than 5×10⁹/cm², for example a density of v-shaped pits of less than 1×10⁹/cm² or less than 5×10⁸/cm².

For example the variable-wavelength LED may comprise a density of v-shaped pits of 1×10⁷/cm² to 5×10⁹/cm², or 5×10⁷/cm² to 5×10/cm², or 1×10⁸/cm² to 5×10⁸/cm².

The variable-wavelength LED may comprise more than 0.1 v-shaped pit per square micrometre, or more than 1 v-shaped pits per square micrometre, or more than 2 v-shaped pits per square micrometre.

The concentration of v-shaped pits in the variable-wavelength LED is preferably controlled, as too many v-shaped pits may negatively affect the light emission of the LED by disrupting radiative recombination. For example the LED may comprise fewer than 10 v-shaped pits per square micrometre, or fewer than 8 v-shaped pits per square micrometre, or fewer than 6 v-shaped pits per square micrometre.

In a preferred embodiment the LED structure may comprise no greater than 10\hat{ }9 threading dislocations per square centimetre. Preferably the semiconductor structure below the active light-emitting region (typically a substrate, the porous region and a connecting layer) comprise no more than 10\hat{ }9 threading dislocations per square centimetre. The threading dislocation density is preferably limited to this level so that further epitaxial growth does not create too many v-shaped pits in the light-emitting region.

Both the density and size (the depth) of the v-shaped pits may be controlled. The size of the V-pits can be controlled by the position and the growth conditions of the pre-strain layer and the low-temperature nGaN layer where the pits started.

The morphology of quantum wells (QWs) in the active light-emitting region may be varied. For example the light-emitting region may contain uniform QWs with well-defined interfaces or fragmented QWs with less well-defined interfaces, fragmentation, or QW well width/composition fluctuation or quantum dot like localisation centres. This control of QW morphology can determine the range of the variable emission wavelength to be controlled and manipulated.

The light-emitting region preferably comprises a plurality of quantum wells (QWs). The quantum wells may be continuous. The quantum wells may be fragmented, or discontinuous.

If QWs are continuous and very uniform in thickness and composition, recombination of charge carriers can only happen in regular well defined ways. On the other hand, if QWs are fragmented or discontinuous, this creates lots of nanostructures, which in turn creates different band gaps that result in emission of different colours.

The light-emitting region, and/or the LED, may have lateral dimensions (width and length) of greater than 100 μm and less than 300 μm. In this case, the LED may be termed a “mini-LED”. In preferred embodiments, the mini-LED may be square or circular or square with circular corners and have dimensions such as 300 μm×300 μm, 200 μm×200 μm, 100 μm×100 μm.

The light-emitting region, and/or the LED, may alternatively have lateral dimensions (width and length) of less than 100 μm. In this case, the LED may be termed a “micro-LED”. The micro-LED may preferably have lateral dimensions of less than 80 μm, or 70 μm, or 60 μm, or 50 μm or 30 μm, or 25 μm, or 20 μm, or 15 μm or 10 μm, or 5 μm or 3 μm or 2 μm.

In preferred embodiments, the micro-LED may be square or circular or square with circular corners and have dimensions such as 75 μm×75 μm, 50 μm×50 μm, 40 μm×40 μm, 30 μm×30 μm, 25 μm×25 μm, 20 μm×20 μm or 10 μm×10 μm, or 5 μm×5 μm, or 2 μm×2 μm, or 1 μm×1 μm, or 500 nm×500 nm or smaller.

The light-emitting region, and/or the LED, may alternatively have lateral dimensions (width and length) of less than 1 μm. In this case, the LED may be termed a “nano-LED”. The nano-LED may preferably have lateral dimensions of less than or 500 nm, or 200 nm, or 100 nm, or 50 nm.

The LEDs may be circular, triangle, rectangular, square, oval, diamond, hexagonal, pentagonal, and any combination of these shapes. In the case of irregular-shapes of pixel design, at least one dimension should fall within the dimensions defined above in order for the LEDs to be classed as mini- or micro-LEDs. For example the width or diameter of the LEDs are preferably less than 100 μm so that the LEDs are classed as micro-LEDs.

### Porous Regions

The variable-wavelength LEDs preferably comprise one or more porous regions of III-nitride material.

The n-type region, the light-emitting region and the p-type region (which may be called the LED structure, or LED diode structure) are preferably grown over a semiconductor template which contains the porous region. The semiconductor template may also contain a number of layers of semiconductor material arranged to provide a suitable substrate for the overgrowth of the LED structure.

The porous region may be a porous layer, such that the light emitting diode comprises a porous layer of III-nitride material. Preferably the porous region may be a porous layer that is continuously porous, for example formed from a continuous layer of porous III-nitride material.

The porous region may comprise a plurality of porous layers, and optionally a plurality of non-porous layers. In preferred embodiments of the invention, the porous region is a stack of alternating porous and non-porous layers, with the top surface of the stack defining the top of the porous region, and the bottom surface of the stack defining the bottom of the porous region. The light-emitting region may be formed over a porous region comprising a stack of porous layers of III-nitride material.

Each variable-wavelength LED may comprise its own porous region of III-nitride material, or alternatively a shared porous region may be epitaxially connected to a plurality of the variable-wavelength LEDs.

### Method of Manufacture of Variable-Wavelength LED

A variable-wavelength LED epitaxial device structure may be manufactured by a method comprising the step of growing:
an n-doped portion;
a p-doped portion; and
a light-emitting region located between the n-doped portion and a p-doped portion, the light-emitting region comprising a light-emitting layer which emits light at a peak emission wavelength under electrical bias thereacross.

The method may comprise the step of overgrowing the n-doped portion, the p-doped portion and the light-emitting region over a porous region of III-nitride material.

The method may comprise the step of forming a porous region of III-nitride material in at least one of the n-doped portion or the p-doped portion, and forming the light-emitting region over a porous region of III-nitride material.

The method may optionally comprise the step of removing the porous region from the LED structure (the n-doped portion, the p-doped portion and the light-emitting region) after the n-doped portion, the p-doped portion and the light-emitting region have been formed.

The light-emitting layer may emit light at a peak emission wavelength between 400 and 800 nm, or between 450-800 nm, or between 500 and 800 nm, or between 550 and 800 nm, or between 610 and 800 nm under electrical bias thereacross.

The LED structure, including the n-doped portion, the p-doped portion, and the light-emitting region, may be an LED structure for emitting at a wavelength lower than the peak emission wavelength of the LED, so that the porous region of III-nitride material red-shifts the emission wavelength of the light-emitting region to the peak emission wavelength.

The n-doped portion, the p-doped portion and the light-emitting region are preferably formed from III-nitride semiconductor material.

In a preferred embodiment, the light-emitting region may comprise a light-emitting indium gallium nitride layer for emitting at a peak wavelength of 500 nm-550 nm or 550 nm-600 nm,
wherein overgrowth on the porous region of III-nitride material shifts the emission wavelength of the light-emitting region to a peak wavelength between 600 and 750 nm under electrical bias.

The light-emitting region may comprise a light-emitting indium gallium nitride layer for emitting at a peak wavelength of 500-550 nm, or 500-580 nm, or 510 to 570 nm, or 530 nm to 560 nm, or 550 nm to 600 nm. The light-emitting indium gallium nitride layer may be one or more layers known to emit at these wavelengths when grown in conventional LEDs, for example on non-porous GaN substrates. However, the inventors have found that growing conventional yellow or green LED structures over a porous III-nitride layer leads to an LED that emits at a peak wavelength between 600 and 750 nm under electrical bias.

The method may comprise the step of growing a yellow or green LED structure over a porous region of III-nitride material.

In preferred embodiments, the light emitting layer is a light-emitting indium gallium nitride layer. The LED preferably also comprises a region of GaN material. Due to the lattice mismatch between GaN and InGaN, the stress relaxation effect created by the porous region is particularly advantageous.

The method may comprise the step of forming the light emitting active region with carrier localisation centres in the quantum wells (which are preferably InGaN QWs). such as multiple types of QW region with different Indium composition and well width and quantum barriers, non-uniform, or fragmented, or broken, or gappy, or discontinuous quantum wells which would result in fluctuation in the well width, InGaN quantum dots or nanostructures, quantum wells formed on polar, semi-polar or non-polar facets.

The method may comprise the step of forming a plurality of quantum wells (QWs), in which the quantum wells are non-uniform, fragmented, or discontinuous.

The plurality of QWs may comprise fluctuations in indium composition, and/or well width fluctuations.

The method may comprise the step of forming one or more v-shaped pits in the LED structure, so that the v-shaped pit extends through the thickness of the light-emitting region. Preferably the method comprises the step of forming at least 0.1 v-shaped pits per square micrometre, or at least 1 v-shaped pits per square micrometre, or at least 2 v-shaped pits per square micrometre. Preferably the method comprises the step of forming a density of v-shaped pits in the light-emitting region of at least 1×10⁷/cm², for example at least 5×10⁷/cm² or at least 1×10⁸/cm², for example a density of v-shaped pits of 1×10⁷/cm² to 5×10⁹/cm². Preferably the method comprises the step of forming a density of v-shaped pits in the light-emitting region of less than 5×10⁹/cm², for example a density of v-shaped pits of less than 1×10⁹/cm² or less than 5×10⁸/cm².

V-shaped pits are a phenomenon known in the art of epitaxial semiconductor growth, and methods of growing v-shaped pits in semiconductor structures are known in the art. For example, v-shaped pits and their growth are described in the prior art in The effect of nanometre-scale V-pits on electronic and optical properties and efficiency droop of GaN-based green light-emitting Diodes; Zhou et al; Scientific Reports |(2018) 8:11053| DOI: 10.1038/s41598-018-29440-4.

V-shaped pits may be grown in the semiconductor structure so that they terminate in a layer below the active light-emitting region. This means that the v-shaped pits must extend through the thickness of the active light-emitting region.

V-shaped pits may be grown from threading dislocations in the semiconductor structure by controlling the growth conditions during epitaxial deposition of layers above a layer containing a threading dislocation. The threading dislocations are perpetuated upwards through the structure as additional layers are grown over layers containing a threading dislocation, and by controlling growth conditions the dislocation is widened into a v-shaped pit.

V-shaped pits can alternatively be grown using 3-dimensional epitaxial growth modes. 3D epitaxial deposition techniques are known in the art and are typically used to grow “islands” or “pyramids” of semiconductor material on a template. By controlling deposition of the LED structure using 3D epitaxial deposition techniques, v-shaped pits can be artificially grown in desired locations, with no need for a threading dislocation to be present to “seed” the formation of the v-shaped pit. By using this deposition control, the bottom (nadir) of the pit may be created at a desired location in the structure-both a desired lateral position and a desired height in the structure, for example in a particular layer of the semiconductor structure below the active light-emitting region.

The bottom of the v-shaped pit may be located in the connecting layer of the semiconductor structure. The connecting layer may be positioned between the porous region and the n-doped portion.

The bottom of the v-shaped pit may be located in a pre-strain layer of the semiconductor structure. The pre-strain layer may be positioned above the n-doped portion and below the light-emitting region.

Preferably the LED comprises a plurality of v-shaped pits which extend through the active light-emitting region.

Both the density and size (the depth) of the v-shaped pits may be controlled. The size of the V-pits can be controlled by the position and the growth conditions of the pre-strain layer and the low-temperature nGaN layer where the pits started.

Quantum wells (QWs) in the active light-emitting region may be deposited so that the quantum wells are continuous and/or of uniform thickness. Alternatively quantum wells (QWs) in the active light-emitting region may be deposited so that the quantum wells are fragmented, or discontinuous.

### Manufacturing Steps

During manufacture of the array of variable-wavelength LEDs which form the pixel matrix of the device, the n-type region, the light-emitting region and the p-type region (which may be called the LED structure) of the variable-wavelength LEDs are preferably grown over a semiconductor template which contains the porous region. The semiconductor template may also contain a number of layers of semiconductor material arranged to provide a suitable substrate for the overgrowth of the LED structure.

The method may comprise the first step of electrochemically porosifying a layer of III-nitride material, to form the porous region of III-nitride material. This may be achieved using a wafer scale porosification process as set out in international patent applications PCT/GB2017/052895 (published as WO2019/063957) and PCT/GB2019/050213 (published as WO2019/145728).

The method may preferably comprise the step of forming the porous region of III-nitride material by electrochemical porosification through a non-porous layer of III-nitride material, such that the non-porous layer of III-nitride material forms a non-porous intermediate layer. The non-porous intermediate layer may advantageously provide a smooth surface for overgrowth of further layers, such as one or more connecting layers of III-nitride material.

The porous region may be formed by porosifying one or more layers or regions of III-nitride material on a substrate. The substrate may be Silicon, Sapphire, SiC, β-Ga2O3. The crystal orientation of the substrates can be polar, semi-polar or non-polar orientation. The substrate thickness may typically vary between 100 μm and 1500 μm.

The porous region may be a porous layer, such that the method comprises the step of overgrowing, over a porous layer of III-nitride material: an n-doped portion; a p-doped portion; and an LED light-emitting region. Preferably the porous region may be a porous layer that is continuously porous, for example formed from a continuous layer of porous III-nitride material.

The porous region may comprise a plurality of porous layers, and optionally a plurality of non-porous layers. In preferred embodiments of the invention, the porous region is a stack of alternating porous and non-porous layers, with the top surface of the stack defining the top of the porous region, and the bottom surface of the stack defining the bottom of the porous region.

Alternatively the porous region may be a layer of III-nitride material that contains one or more porous regions, for example one or more porous regions in an otherwise non-porous layer of III-nitride material.

In preferred embodiments, the porous region, or porous layer, may have a lateral dimension (width or length) equivalent to that of the substrate wafer on which the porous layer or region is grown. For example, conventional substrate wafer sizes may have a variety of sizes, such as 1 cm², or 2 inch, 4 inch, 6 inch, 8 inch, 12 inch, or 16 inch diameter. By patterning one or more layers and/or depositing regions of different charge carrier concentrations in the same layer, however, smaller porous regions can be formed that do not span the entire substrate. The lateral dimensions of the porous layer or region may therefore vary from around 1/10 of a pixel (for example 0.1 μm), up to the lateral dimensions of the substrate itself.

Prior to the porosification step, a doped region of n-doped III-nitride semiconductor material, preferably containing a layer, or stack of layers, may be deposited on a substrate. The III-nitride layer(s) may contain one or a combination of these elements: Al, Ga, In (ternary of quaternary layer). The thickness of the III-nitride stack is preferably between 10-4000 nm. The III-nitride region may have a doping concentration between 1×10¹⁷ cm⁻³-5×10²⁰ cm⁻³.

Preferably an intermediate layer of undoped III-nitride material is deposited over the doped material before it is porosified. The intermediate layer preferably has a thickness of between 1 nm and 3000 nm, preferably between 5 nm and 2000 nm. As the intermediate layer is undoped, it remains non-porous after the porosification step, which advantageously provides a good surface for epitaxial overgrowth of further layers of semiconductor.

In preferred embodiments, the doped region consists of an alternating stack of doped and undoped layers. In preferred embodiments the stack contains between 5-50 pairs of layers. The thickness of each highly doped layer may vary between 10 nm-200 nm and low-doped or undoped layers may have a thickness of between 5-180 nm.

As is known in the art, electrochemical porosification removes material from n-type doped regions of III-nitride materials, and creates empty pores in the semiconductor material.

In preferred embodiments, the LED structure is formed over a stack of multiple porous layers of III-nitride material. Thus, rather than being a single porous layer of III-nitride material, the porous region may be a stack of layers of III-nitride material in which at least some layers are porous. The stack of porous layers may preferably be a stack of alternating porous and non-porous layers.

The method may preferably comprise the step of depositing one or more connecting layers of III-nitride material on the surface of the intermediate layer of III-nitride material prior to overgrowing the n-doped region, the LED light-emitting region and the p-doped region on the connecting layer.

Alternatively, where there is no non-porous intermediate layer over the porous region, the method may comprise the step of depositing a connecting layer of III-nitride material onto the surface of the porous region of III-nitride material.

The method may comprise the further step of overgrowing the n-doped region, the LED light-emitting region and the p-doped region on the connecting layer.

### BRIEF DESCRIPTION OF THE DRAWINGS

Embodiments of the invention will now be described with reference to the figures, in which:

FIG. 1 illustrates a CIE xy colour gamut and the wavelengths directly emittable by an exemplary variable-wavelength LED usable in the present invention;

FIG. 2 illustrates the colour gamut of FIG. 1, overlaid with a palette of 6 available primaries;

FIG. 3 illustrates the colour gamut of FIG. 2, overlaid with a plurality of colour-mixing lines;

FIG. 4 illustrates the colour gamut of FIG. 1, overlaid with the white-point;

FIG. 5 illustrates the colour gamut of FIG. 3, overlaid with a plurality of colour-mixing triangles containing the white-point;

FIG. 6A-6D illustrate, as 3D colour volumes, the respective colour gamuts displayable using the method of the present invention with different first primary emission wavelengths;

FIGS. 7A-7C illustrate, as 3D colour volumes, the respective colour gamuts displayable using a conventional sRGB display, a variable-wavelength LED display according to the present invention, and Rec. 2020;

FIG. 8 is a series of five EL images of the same MicroLED pixel being driven at different currents in constant wave mode (CW), showing five different colours of emission;

FIG. 9A is an emission wavelength vs current density plot for a 25 μm×25 μm 100×100 variable-wavelength LED pixel array driven in pulsed mode with a 100 μs pulse at 1% duty cycle;

FIG. 9B is an emission wavelength vs current density plot for a 30 μm×30 μm 100×100 variable-wavelength LED pixel array driven in pulsed mode with a 100 μs pulse at 1% duty cycle;

FIG. 10 is a plot of intensity vs wavelength for a single variable-wavelength LED driven at different currents in pulsed driving mode with a 100 μs pulse at 1% duty cycle;

FIGS. 11A-G illustrate alternative embodiments of non-uniform, fragmented or discontinuous light-emitting regions of variable-wavelength LEDs usable in preferred embodiments of the present invention;

FIG. 12A is a TEM image of a cross-section of a conventional non-variable-wavelength LED;

FIG. 12B is a TEM image of the light-emitting region of a variable-wavelength LED comprising v-shaped pits, usable in embodiments of the present invention;

FIG. 12C is a TEM image of the variable-wavelength LED of FIG. 12B, showing a porous region and a light-emitting region comprising a plurality of v-shaped pits, usable in a preferred embodiment of the present invention;

FIG. 13A is a graph of peak emission wavelength vs driving current density for a conventional non-variable wavelength LED;

FIG. 13B is a graph of peak emission wavelength vs driving current density for a variable-wavelength LED according to an embodiment of the present invention;

FIG. 13C is a graph of peak emission wavelength vs driving current density for a variable-wavelength LED according to another embodiment of the present invention;

FIG. 14A is a graph of peak emission wavelength vs driving current density for another variable-wavelength LED usable in embodiments of the present invention;

FIGS. 14B-D are photographs of the variable-wavelength LED of FIG. 14A, with inset emission spectra showing the different peak emission wavelengths at different driving current densities.

As described above, an optoelectronic display device containing a variable-wavelength LED can be operated to display any chromaticity within a displayable colour gamut, by selecting a plurality of primary emission wavelengths, and emitting those primary wavelengths in combination to provide a combined output signal with the desired output chromaticity and output luminance.

The size of the colour gamut which is achievable depends on the wavelengths of the primaries selected.

A variable-wavelength LED is used to emit at least one of the primary emission wavelengths.

In preferred embodiments, the same variable-wavelength pixel is used to emit all of the selected primaries using field-sequential emission. In this case, all of the primary emission wavelengths are selected to be within the emission wavelength range of the variable-wavelength LED.

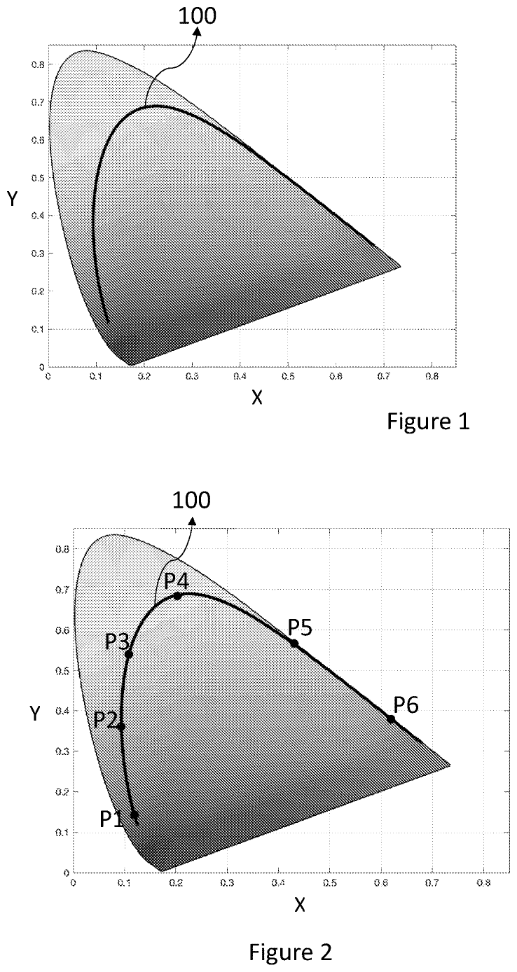

FIG. 1 illustrates the emission wavelength range (indicated by line 100) of one such variable-wavelength LED usable in the present invention, plotted in CIE xy colour space. However, this is a misleading way of illustrating color gamut, because it does not show intensity. CIE xy is not a perceptual space—the relative areas on this chart have no correlation to quality—and green is over-represented. For this reason, it is preferable to work with reference to a 3D color volume in a perceptual color space (Munsell L*a*b*).

FIG. 1 illustrates a CIE xy color space plot, on which the wavelengths emittable by a variable-wavelength LED are indicated as a continuous black line 100. By varying the driving conditions, such as the magnitude of the driving current or the driving voltage, provided to the LED, the wavelength of light which is directly emitted by the LED may be tuned to any wavelength along line 101.

FIG. 2 is a CIE xy color space plot 200 which illustrates the same emission line 101 as shown in FIG. 1, overlaid with 6 points representing “primaries” P1, P2, P3, P4, P5, P6. These six primaries are specific emission wavelengths which have been selected from the continuous line of emittable-wavelengths 100. The six respective driving conditions required to be supplied to the variable-wavelength LED to result in these six emission wavelengths can be easily found, and those six driving conditions can be programmed into a display device. During operation, those six driving conditions can be supplied to the variable-wavelength LED, leading to the LED emitting light at any one of the six primary wavelengths. The space bounded by the six primaries is the colour gamut of colours which are displayable using the variable-wavelength LED and these six primary wavelengths.

In reality, the palette of N available primary emission wavelengths may contain more than 6 primaries.

By driving the variable-wavelength LED using field-sequential driving, different driving conditions can be supplied to the LED during discrete subframe time periods. Thus during a first subframe time period, a first driving condition can be supplied to the LED so that the LED emits light at primary wavelength P1. During a subsequent subframe time period, a different driving condition can be supplied to the LED so that the LED emits light at a different primary wavelength (one of P2-P6). In a preferred embodiment, each display frame contains only three subframes, each of which is assigned to the emission of a different primary. The overall colour which will be observed by an observer viewing the variable-wavelength LED will be a temporal average of the three primary wavelengths emitted during the display frame.

It is possible to divide a display frame into any number of shorter subframes. For example one display frame could be divided into six subframes, so that each of the six primaries could be emitted one after the other within a display frame. However, the present inventors have found that it is desirable to use only a subset of the available primaries during a given display frame, as doing this simplifies colour mixing and reduces the power that is consumed in switching between driving conditions. In order to render a given target colour, a set of three or more primary wavelengths are selected from the available palette of 6 primaries P1-P6, and the selected primaries are then mixed proportionally to give a temporal average which appears to an observer to be the target colour.

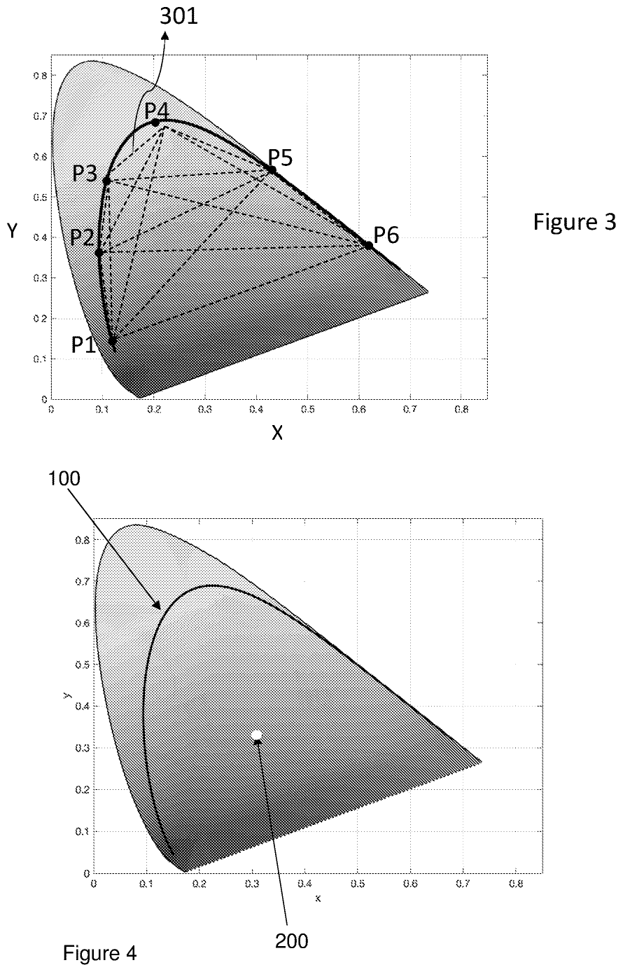

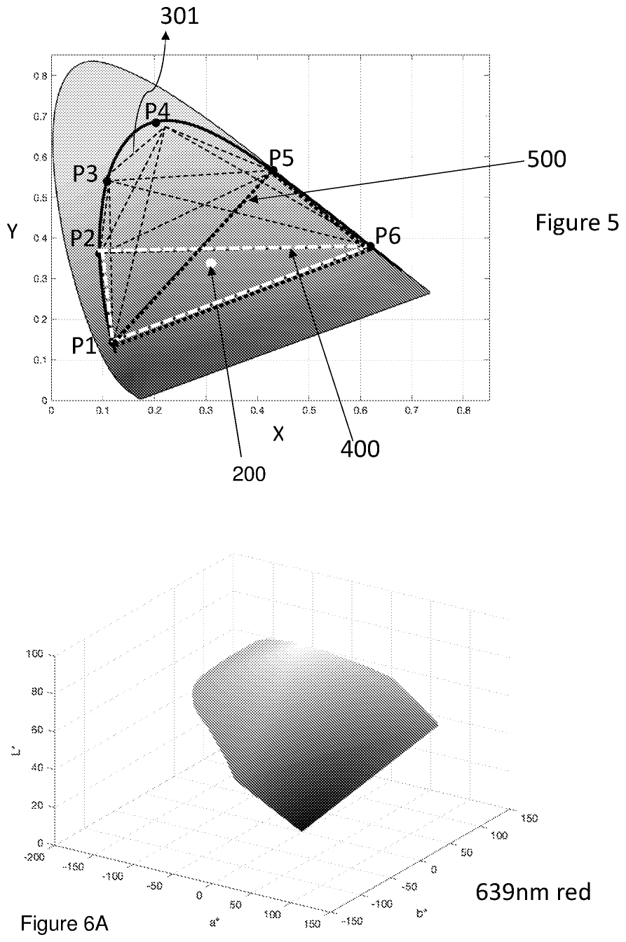

As illustrated in FIG. 3, the palette of 6 available primaries P1-P6 can be divided into a plurality of different combinations. Each pair of primaries can then be linearly mixed with one another to display any colour along the straight lines 301 between the two primary wavelengths. By mixing three primaries, it is possible to display any colour within the triangle bounded by the straight lines 301 between those three primaries. By mixing four primaries, it is possible to display any colour within the quadrilateral bounded by the straight lines 301 between those four primaries.

FIG. 4 illustrates the emission wavelength range (indicated by line 100) of one such variable-wavelength LED usable in the present invention, plotted in CIE xy colour space. The wavelengths emittable by a variable-wavelength LED are indicated as a continuous black line 100. By varying the driving conditions, such as the magnitude of the driving current or the driving voltage, provided to the LED, the wavelength of light which is directly emitted by the LED may be tuned to any wavelength along line 100.

The colour gamut contains white point 200.

Any point on the emission wavelength range line 100 may be used as a primary emission wavelength.

In one preferred embodiment, pairs of primary emission wavelengths may be selected from the palette of N available primary emission wavelengths lying on the emission wavelength range line 100. Pairs of complementary primary emission wavelengths may be positioned on opposite sides of the white point, so that white light may be displayed using a linear mixture of the two selected primary emission wavelengths.

In another embodiment, sets of four primary emission wavelengths may be selected from the palette of N available primary emission wavelengths lying on the emission wavelength range line 100. The four selected primary emission wavelengths may be spread out around the white point, so that the four primaries form the vertices of a colour-mixing quadrilateral on the colour gamut. White light may be displayed using a proportional mixture of the four selected primary emission wavelengths.

In the preferred embodiment illustrated in the Figures, sets of three primary emission wavelengths are selected from the palette of N available primary emission wavelengths lying on the emission wavelength range line 100.

Sets of three complementary primary emission wavelengths are positioned on emission line 100 on opposite sides of the white point 200. Any colour-mixing triangle which contains the white point 200 may be used to display white light by combining the primary emission wavelengths at the vertices of the colour-mixing triangle, in required barycentric-weight proportions.

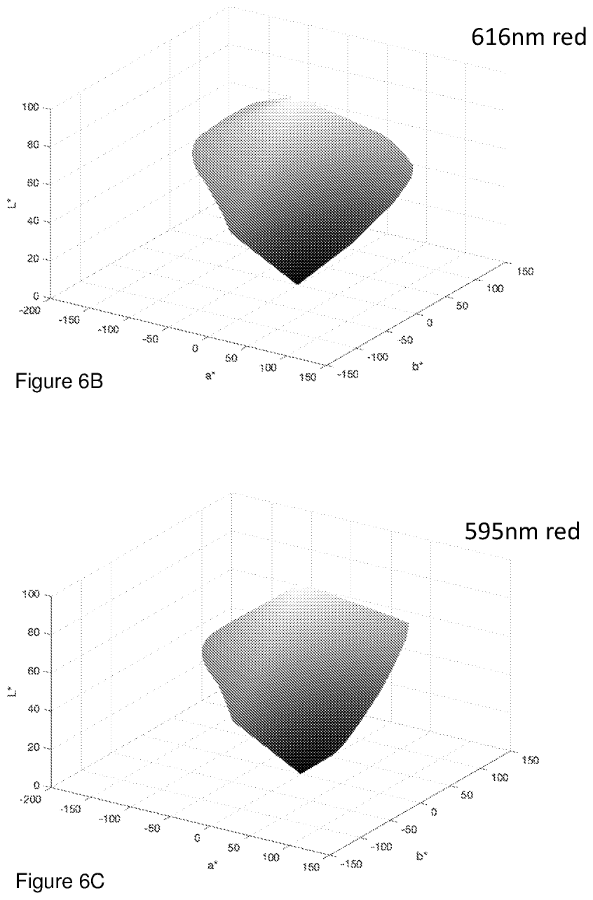

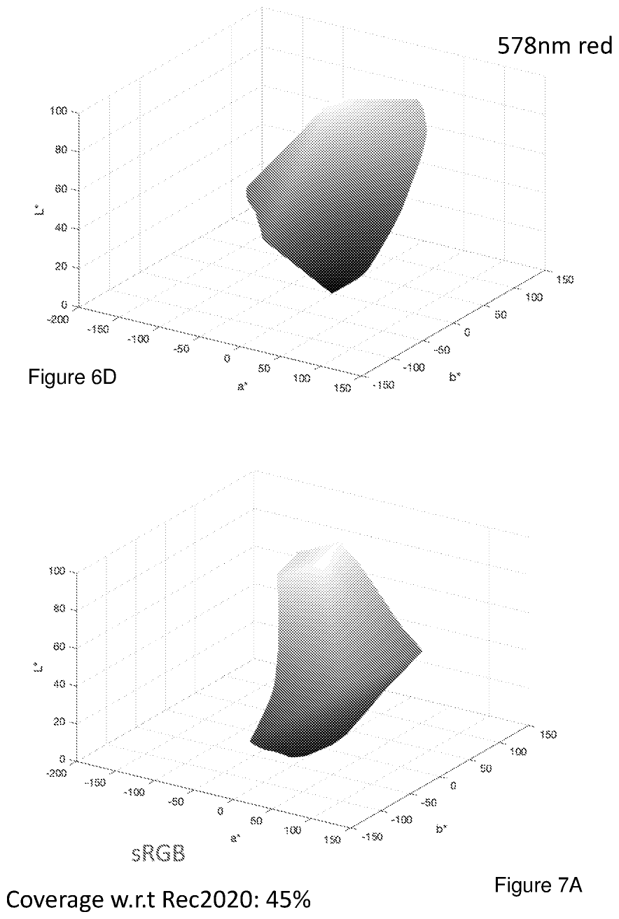

As shown in FIG. 6, multiple colour-mixing triangles contain the white point 200, so multiple sets of three primaries may be used to display white light as an output signal. For example colour-mixing triangle 400 has vertices at P1, P2 and P6 and contains the white point, while colour-mixing triangle 500 has vertices at P1, P5 and P6 and also contains the white point.

As these colour-mixing triangles contain the white point, the primary emission wavelengths at the vertices of the colour-mixing triangles represent a set of complementary primary emission wavelengths which are combinable to display white light. So to display a white light output signal, primaries P1, P2 and P6 could be selected as the set of operating primaries, and mixed in different proportions so that the emitted light forms an output signal that is white light. Alternatively, primaries P1, P5 and P6 could be selected as the set of operating primaries, and mixed in different proportions so that the emitted light forms an output signal that is white light. Alternatively a set of P1, P3 and P6 could be selected, or a set of P1, P4 and P6 could be selected.

When output signals other than white light are desired, any colour-mixing triangle (or colour-mixing quadrilateral in the case of four operating primaries) which contains the desired output chromaticity can be used. Thus the set of primary emission wavelengths which is selected depends on the chromaticity of the output signal which is to be displayed. The display device can operate using a set of any three or more of the N available primary emission wavelengths.

Table 1 illustrates experimental data obtained for a variable-wavelength LED usable in the present invention. Table 1 shows measured conditions from 0.26″ array at 1% APL, in which Wavelength is in units of nm, and L is luminance.

TABLE 1

| Wavelength | FWHM/nm | L/cd/m\hat{ }2 |
|---|---|---|
| 466 | 50 | 1,000,473 |
| 482 | 50 | 880,927 |
| 515 | 50 | 964,512 |
| 517 | 50 | 725,799 |
| 529 | 50 | 429,071 |
| 533 | 50 | 299,851 |
| 545 | 50 | 113,520 |
| 578 | 50 | 12,082 |
| 595 | 50 | 3,264 |
| 616 | 50 | 596 |
| 639 | 50 | 68 |

This shows that the variable-wavelength LEDs emit longer wavelengths at much lower luminances than shorter wavelengths. The low brightness of longer-wavelength primaries can become a limiting factor when high display brightness is desired.

When driving a display comprising a variable-wavelength LED, even though the LED can be driven to emit all of these wavelengths, it is necessary to pick a white-balance condition so that the relative luminances can be set.

In one example embodiment, a set of three primary emission wavelengths is selected to be red, green and blue at 639 nm, 533 nm and 466 nm respectively.

In order for the output signal formed from a combination of these three primaries to make D65 white, the luminances of the red/green/blue primaries must be set in the ratio 1.6:3.6:1 respectively

In order to maximise the brightness of the red primary, the duty cycle of the driving signal for the red primary is set to 100% at 639 nm. This results in the red primary emitting 639 nm with a luminance of 68 cd/m².

The luminances required from green and blue primaries in order to meet the required colour-balance ratio, are calculated as shown in Table 2. Knowing the required luminances for these primaries, duty cycles of the driving signals for the green and blue primaries are computed to meet the white point condition.

The duty cycles for the other wavelengths are a free parameter and are calculated by interpolation

TABLE 2

| | | | | L/cd/m\hat{ }2 after |
|---|---|---|---|---|
| Wavelength | FWHM/nm | L/cd/m\hat{ }2 | Duty cycle | duty cycle |
| 466 | 50 | 1,000,473 | 0.00% | 42 |
| 482 | 50 | 880,927 | 0.01% | 69 |
| 515 | 50 | 964,512 | 0.01% | 124 |
| 517 | 50 | 725,799 | 0.02% | 127 |
| 529 | 50 | 429,071 | 0.03% | 147 |
| 533 | 50 | 299,851 | 0.05% | 154 |
| 545 | 50 | 113,520 | 0.13% | 144 |
| 578 | 50 | 12,082 | 0.98% | 118 |
| 595 | 50 | 3,264 | 3.19% | 104 |
| 616 | 50 | 596 | 14.60% | 87 |
| 639 | 50 | 68 | 100.00% | 68 |

Now we have wavelengths (i.e. chromaticity coordinates) and luminances for all wavelengths in the set.

For this data set, the D65 white-balanced brightness is 264 cd/m².

This is limited by the brightness at the longest wavelength to be used as a primary emission wavelength, where the duty cycle is 100%.

Note the very short blue duty cycles.

In certain scenarios, such a low white-balanced brightness is undesirable, so using the method of the present invention, a less saturated, but brighter, wavelength is selected for the red primary emission wavelength. The newly adjusted red primary emission wavelength is lower, but as it is still driven at 100% duty cycle the luminance for the adjusted red primary emission wavelength is now higher.

An example of this is shown in Table 3, in which 595 nm is selected for use as the red primary emission wavelength, and the duty cycle of the red driving conditions are set to 100% duty cycle. The duty cycles of the unchanged green and blue primaries are increased to maintain the white-balance ratio with the newly increased red luminance. The result of this is that now the three primary emission wavelengths emit a combined output luminance of 7,300 cd/m² out of the display at the D65 white point.

The red emission is now much less saturated, but the output luminance is greatly increased.

TABLE 3

| | | | | L/cd/m\hat{ }2 after |
|---|---|---|---|---|
| Wavelength | FWHM/nm | L/cd/m\hat{ }2 | Duty cycle | duty cycle |
| 466 | 50 | 1,000,473 | 0.12% | 1,191 |
| 482 | 50 | 880,927 | 0.18% | 1,601 |
| 515 | 50 | 964,512 | 0.25% | 2,447 |
| 517 | 50 | 725,799 | 0.34% | 2,498 |
| 529 | 50 | 429,071 | 0.65% | 2,806 |
| 533 | 50 | 299,851 | 0.97% | 2,908 |
| 545 | 50 | 113,520 | 2.53% | 2,877 |
| 578 | 50 | 12,082 | 26.20% | 3,165 |
| 595 | 50 | 3,264 | 100.00% | 3,264 |
| 616 | 50 | 596 | 100.00% | 596 |
| 639 | 50 | 68 | 100.00% | 68 |

As described above, the converse situation is also possible, in which the wavelength of the longest primary emission wavelength is increased to increase the displayable gamut at the cost of reduced output luminance.

FIGS. 6A-6D illustrate, as 3D colour volumes, the respective colour gamuts displayable using the method of the present invention with different first (red) primary emission wavelengths of 639 nm, 616 nm, 595 nm and 578 nm. The longer the red primary emission wavelength, the larger the overall size of the colour gamut displayable by the display device.

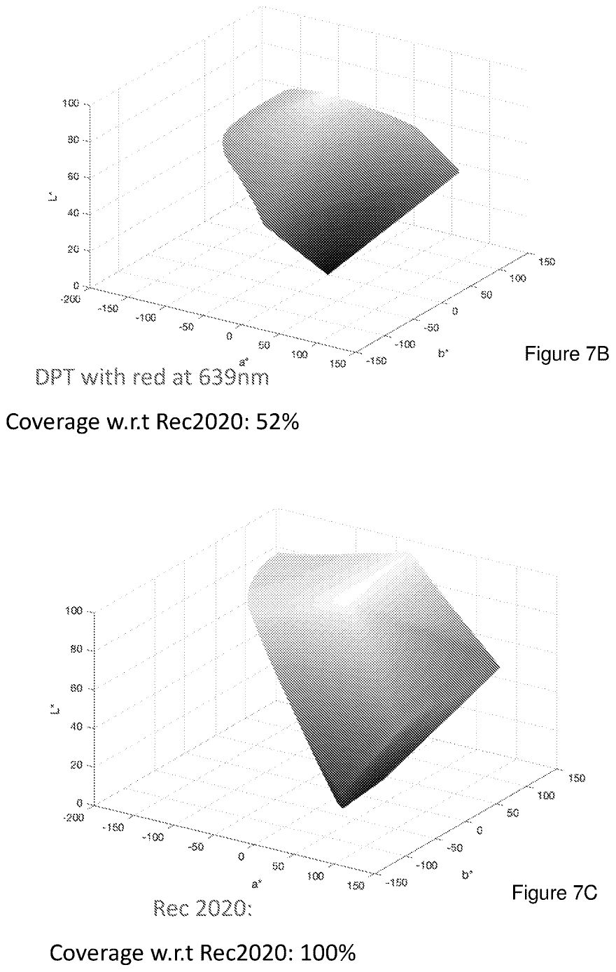

FIG. 7A illustrates, as a 3D colour volume, the colour gamut displayable using a conventional sRGB display. FIG. 7B illustrates the colour gamut displayable using a variable-wavelength LED display according to the present invention. FIG. 7C illustrates the Rec. 2020 (ITU-R Recommendation BT.2020) colour gamut.

With a red primary at 639 nm, green primary at 533 nm and blue primary at 466 nm and all primaries having 50 nm FWHM, DPT already covers more of the Rec 2020 space than SRGB (52% compared to 45%).

### Variable-Wavelength LEDs

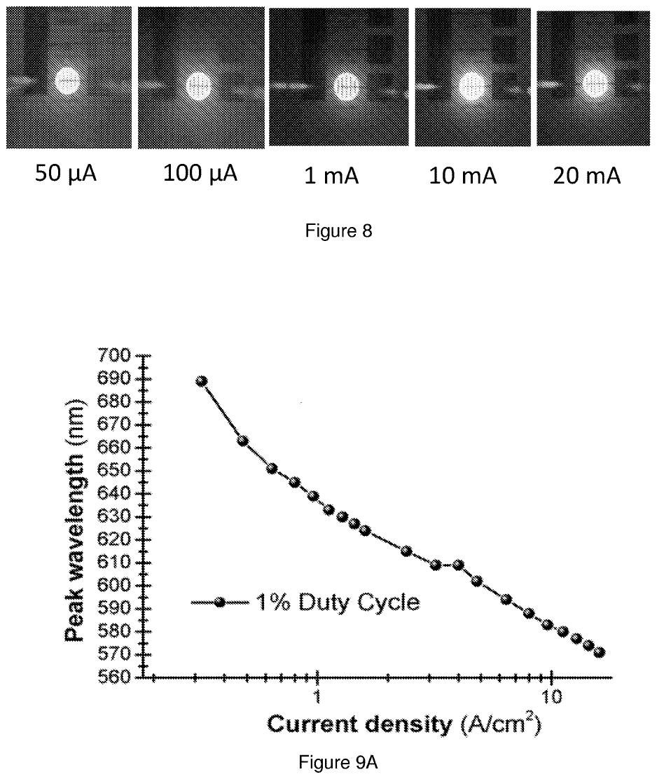

Variable-wavelength LEDs driveable in the present invention are described further above and below with reference to FIGS. 8-14E.

In a particularly preferred embodiment of the present invention, the device epitaxial structure from which all of the device mesas are formed is a variable-wavelength LED epitaxial structure. Particularly advantageously, a single variable-wavelength LED epitaxial structure may be grown over a porous region of III-nitride material at wafer-scale to form a monolithic device wafer comprising an array of variable-wavelength LEDs which are formed from the same materials.

An entire wafer-scale device structure may be formed during a single epitaxial growth process, and then the method of the present invention may be used to process the resulting device wafer into an opto-electronic device in which each separate device mesa acts as a separate variable-wavelength LED.

This provides a large number of possibilities for a display device, as the “colour” (the peak emission wavelength) emitted by each LED can be controlled by controlling the driving current density provided to that particular LED mesa in use.

The driving circuit may thus be configured to drive the variable-wavelength LEDs in the device in a variety of ways depending on the desired result:
Each variable-wavelength LED in the device may be dynamically driven by the driving circuit, with each variable-wavelength LED receiving a drive current density the magnitude of which varies in real time during a display frame, so that the same variable-wavelength LED may be controlled to emit a plurality of different wavelengths during a single display frame.
Each variable-wavelength LED may be driven by the driving circuit with a fixed driving current density, so that the variable-wavelength LEDs behave as fixed-wavelength emitters in use. However, the driving circuit may be configured to provide driving current densities of different magnitudes to different variable-wavelength LEDs in the device. Even though the different variable-wavelength LEDs are formed from the same epitaxy and have the same device structure, the different driving current densities control different device mesas to emit different fixed peak emission wavelengths. Thus by providing different fixed drive conditions to different device mesas, a multi-colour display may be provided from a single device epitaxy.
A mixture of these two options may also be provided, with the driving circuit being configured to control some device mesas in the device dynamically, and to control other device mesas as fixed-wavelength emitters by providing a fixed driving current to those mesas.

During manufacturing, the size, shape and position of the variable-wavelength LEDs may be controlled by controlling the size, shape, depth and position of trenches etched into the device wafer.

By forming all of the separate device mesas from a single wafer epitaxy, it is possible to eliminate many of the time-consuming, low-yield and expensive processing steps required for device integration in the prior art.

In preferred embodiments of the present invention, the driving circuit and some or all of the variable-wavelength LEDs are preferably configured to receive a variable-magnitude supply of driving current from the driving circuit, so that the magnitude of the driving current to each variable-wavelength LED is variable. By varying the magnitude of the driving current to a variable-wavelength LED, the peak emission wavelength of that LED can be varied as the display device is used. The driving current provided to each variable-wavelength LED may be individually controllable, so that the peak emission wavelength of each variable-wavelength LED in the display may be controlled and varied individually. Alternatively, the device and the driving circuit may be configured so that the same driving conditions are provided to a group of variable-wavelength LEDs simultaneously, so that all of the variable-wavelength LEDs in that group emit light at the same peak emission wavelength when the driving current is on, and the peak emission wavelength of the entire group can be varied by varying the magnitude of the driving current.

In alternative embodiments, the driving circuit may be configured to provide a fixed-magnitude (i.e. non-variable) driving current, which is either on or off, to some or all of the variable-wavelength LEDs in the display device. When the fixed driving current is on, those variable-wavelength LEDs will behave as conventional LEDs, and emit at a single peak emission wavelength determined by the driving conditions provided to the LEDs. Thus variable-wavelength LEDs which are configured to receive a fixed-magnitude driving current may be used as fixed-emission-wavelength LEDs in the display device.

Preferably the driving circuit is configured to control at least one subpixel of each pixel as a dynamic variable-wavelength LED, the peak emission wavelength of which may be varied within a single display frame.

The driving circuit may be configured to separately control the driving current provided to each of the plurality of LEDs, so that each of the plurality of LEDs is individually driveable. The driving circuit may be configured to provide a plurality of different driving currents to the plurality of LEDs, so that separate LEDs are driveable to emit at different peak emission wavelengths in response to the different driving currents.

Alternatively, the driving circuit may be configured to separately control a groups of two or more LEDs, so that each LED in a group emits at the same peak emission wavelength. The driving circuit may be configured to provide different driving currents to different groups of LEDs, so that separate groups of LEDs are driveable to emit at different peak emission wavelengths in response to the different driving currents.

FIG. 8 is a series of five EL images of the same variable-wavelength MicroLED InGaN pixel being driven at different currents in constant wave mode (CW), showing five different colours of emission. In the left-hand image, the micro-LED emission colour is seen to be red at a driving current of 50 μA. In the second image from the left, the micro-LED emission colour is seen to be red-orange at a driving current of 100 μA. In the third image from the left, the micro-LED emission colour is seen to be orange at a driving current of 1 mA. In the fourth image from the left, the micro-LED emission colour is seen to be yellow-green at a driving current of 10 mA. In the right-hand image, the micro-LED emission colour is seen to be green at a driving current of 20 mA.

By varying the driving current between 50 μA to 20 mA, the same micro-LED is therefore capable of emitting at wavelengths ranging from red to green. The spectral width of this emission wavelength range is on the order of 90 nm (from around 570 nm to around 660 nm). This is a far greater range of emission wavelengths than has ever been achievable with a single LED in the prior art.

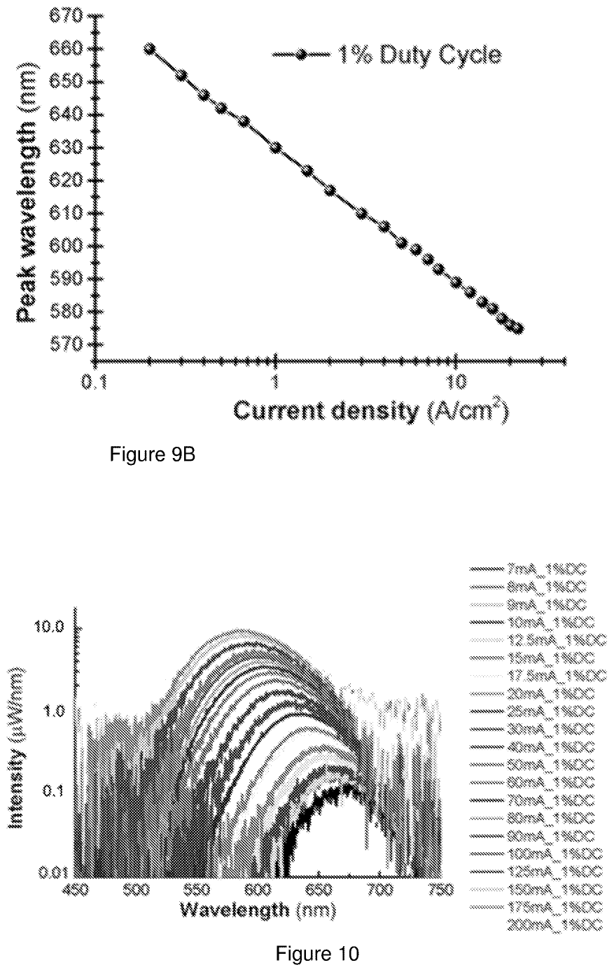

FIG. 9A is an emission wavelength vs current density plot for a 25 μm×25 μm InGaN LED pixel array (100×100 array, containing 10,000 pixels) driven in pulsed mode with a 100 μs pulse at 1% duty cycle. FIG. 9B is an emission wavelength vs current density plot for a 30 μm×30 μm InGaN LED pixel array (100×100 array, containing 10,000 pixels) driven in pulsed mode with a 100 μs pulse at 1% duty cycle.

Both of these plots show the controllability of the peak emission wavelength with a pulse driven power supply. In particular, the wavelength is linearly dependent on the current density (plotted on a logarithmic scale). This linearity can equally be manipulated when driving with a pulsed voltage power supply. The variable emission wavelengths of the LED can therefore be controlled with either voltage or current driving schemes in either CW or pulsed mode, all of which are standard ways of display driver IC.

This linear relationship between the driving current density and the resulting emission wavelength is highly advantageous for the purposes of LED display design, as it enables accurate control of the emission wavelengths by varying the current density of the power supply.

FIG. 10 is a plot of intensity vs wavelength for a variable-wavelength InGaN LED driven at different DC currents. The power supply is operated in pulsed driving mode with a 100 us pulse at 1% duty cycle.

FIG. 10 again reflects a gradual, continuous transition of the peak emission wavelength of the LED as the current of the power supply is varied. At a driving current of 200 mA, the peak emission wavelength is around 575 nm, with an intensity of around 10 μW/nm. As the driving current is reduced, however, the peak emission wavelength moves gradually to longer wavelengths, and to lower emission intensities. When the driving current reaches 7 mA, the peak emission wavelength is approximately 675 nm, with an intensity of around 0.1 μW/nm.

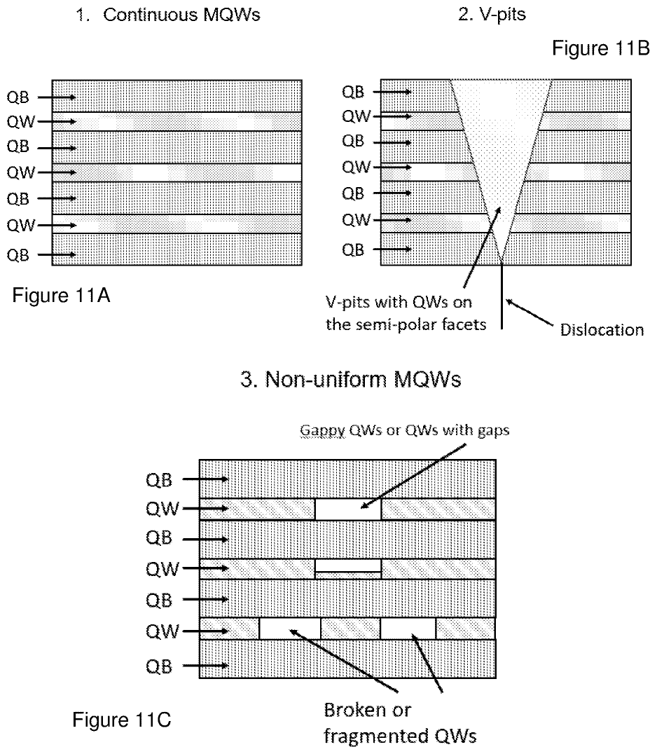

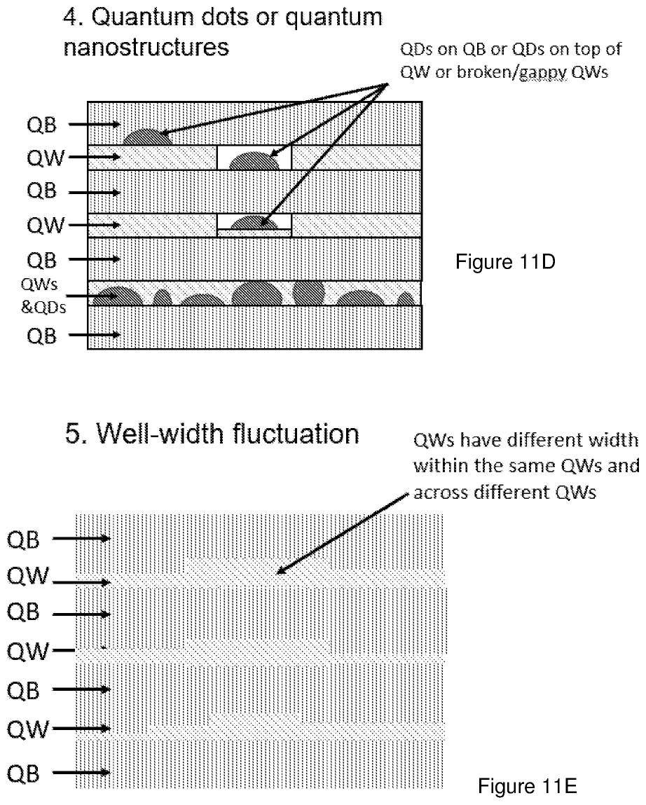

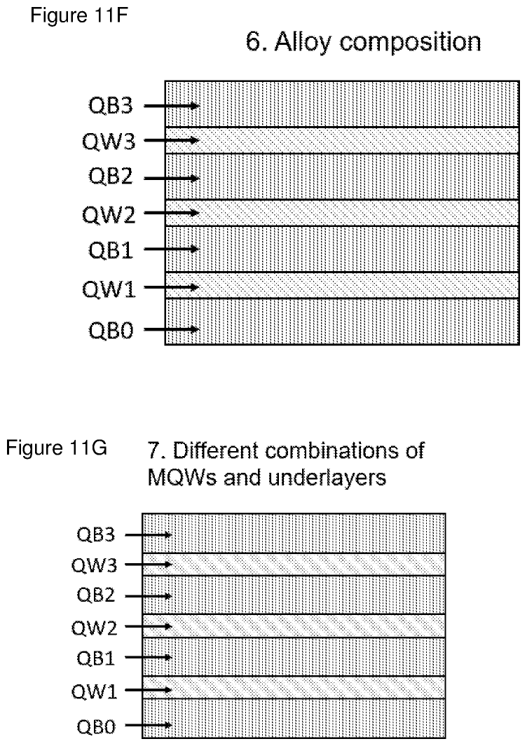

FIGS. 11A-G illustrate alternative embodiments of light-emitting regions of variable-wavelength LEDs which can be used as semiconductor devices in embodiments of the present invention.

### Examples of MQWs:

1. Continuous MQWs
2. V-pits
3. Broken QWs, gappy QWs, fragmented QWs
4. QDs
5. Well-width fluctuation
6. Alloy composition
7. Different combinations of MQWs and underlayers

These structural characteristics can be identified and examined by standard material characterisation techniques, such as cross-sectional transmission electron microscopy (TEM), X-ray diffraction (XRD), Energy Dispersive X-ray Spectroscopy (EDX or EDS), 3D atom probe (3DAP).

FIG. 11A shows a continuous MQW light-emitting region of an LED, in which three identical QWs are provided between four identical quantum barriers (QBs).

FIG. 11B shows the continuous MQW of FIG. 11A, with a V-shaped pit propagating through the light-emitting region. The v-shaped pit terminates in a threading dislocation, and has QWs on its semi-polar facets.

FIG. 11C shows a MQW in which the QW layers comprise discontinuities or gaps in the semiconductor material.

FIG. 11D shows a MQW in which quantum dots (QDs) create non-uniformities in the MQW. QDs may be provided on or in the QB or QW layers, for example in gaps in the QW structure.

FIG. 11E shows a MQW with well-width fluctuation, in which the thicknesses of the QW layers are not uniform across the light-emitting region. The QWs may have different widths from each other, and also varying widths within a single QW.

FIG. 11F shows a MQW with fluctuations in alloy composition in the light-emitting region. The compositions of the QBs and the QWs differ from layer to layer. In particular, the indium In % composition is varying within the same QWs, i.e. in QW2, In % is varying between 10-12% or 10-15%, or 10-25%, or 10-35%.

FIG. 11G shows a MQW containing different combinations of MQWs and underlayers. In % composition is different across different QWs. For example In % in QW1 is 15%, In % in QW2 is 25%, and In % in QW3 is 30%. In embodiments of the present invention, the lower In % QW is preferably positioned at the bottom of the MQW, due to its strain and thermal effect, while the high In % QWs is preferred to be on the top. In a preferred embodiment, for example, QW1 is a blue emitting QW, QW2 is a green emitting QW, QW3 is a red emitting QW.

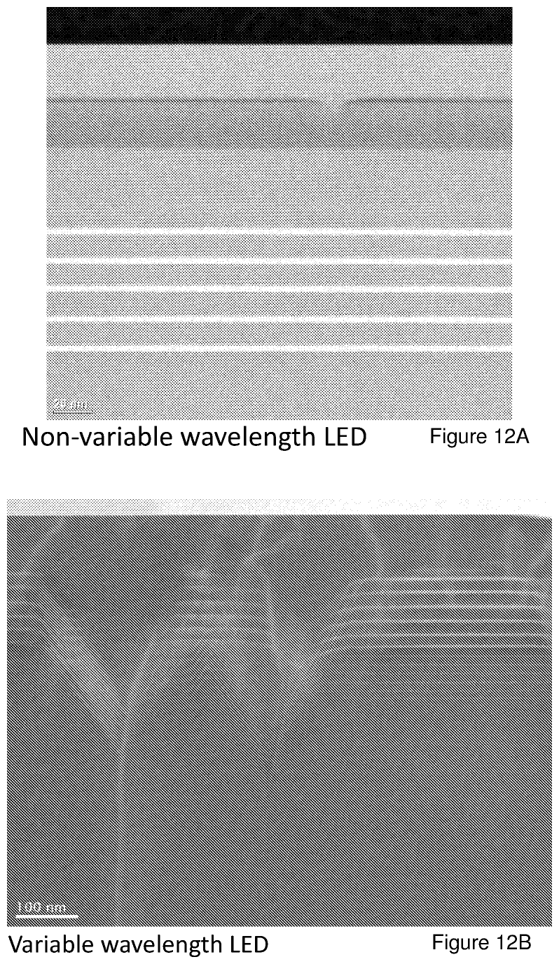

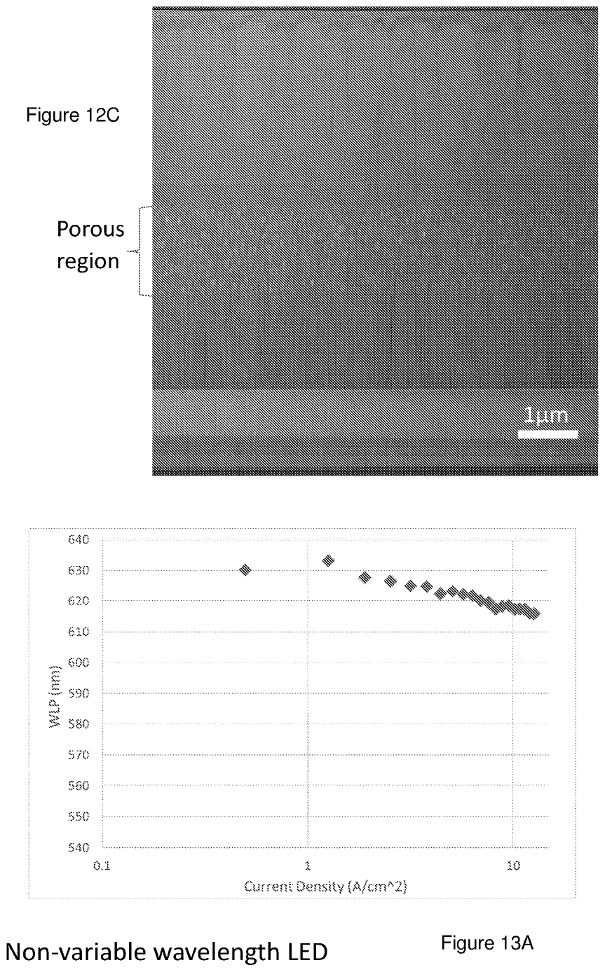

FIG. 12A is a TEM image of a cross-section of a conventional non-variable-wavelength LED. In this non-variable-wavelength LED, the MQWs are uniform and smooth in both upper and lower interface (5 MQWs shown here).

FIGS. 12B and 12C are TEM images a variable-wavelength LED comprising v-shaped pits, usable in an embodiment of the present invention. In this variable-wavelength LED, the MQWs are non-uniform. This non-uniformity can be induced by various methods, one example is v-pits and the semi-polar facets which would incorporate more indium and thinner QWs. Another example is also shown in FIG. 11B, that the MQWs are not uniform, in terms of broken QWs, discontinuous QWs, fragmented QWs, QWs with well-width or In composition fluctuation.

FIG. 12C shows a cross section of the variable-wavelength LED of FIG. 12B, showing a porous region and a light-emitting region comprising a plurality of v-shaped pits, usable in a preferred embodiment of the present invention.

In this structure, the light-emitting region contains multiple emission wavelength regions that are deliberately introduced such as multiple types of QW region with v-shaped pits extending through the light-emitting region.

V-shaped pits (V-pits) are actually hexagonal pits looking from the above, v-shape is when looking at the cross-section. V-pits can be initialize at each site of dislocations under special epitaxy growth conditions during the growth of InGaN, GaN, InGaN/InGaN superlattice, or InGaN/GaN superlattice structures underlying the MQWs, such as low growth temperature (e.g. <1000° C., or <900° C., or <800° ° C., or <700° C.) and nitrogen ambient.

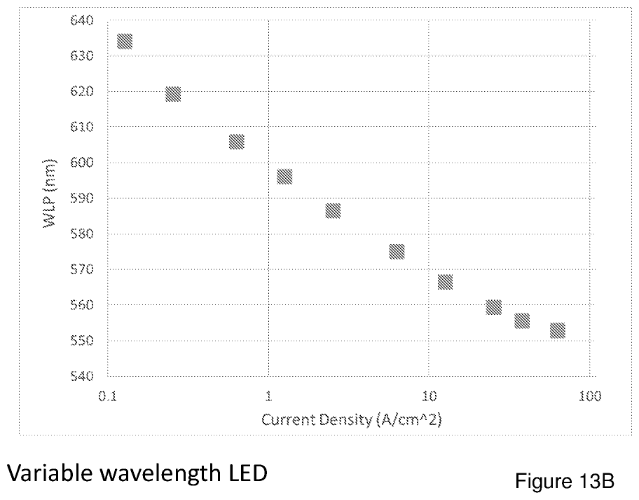

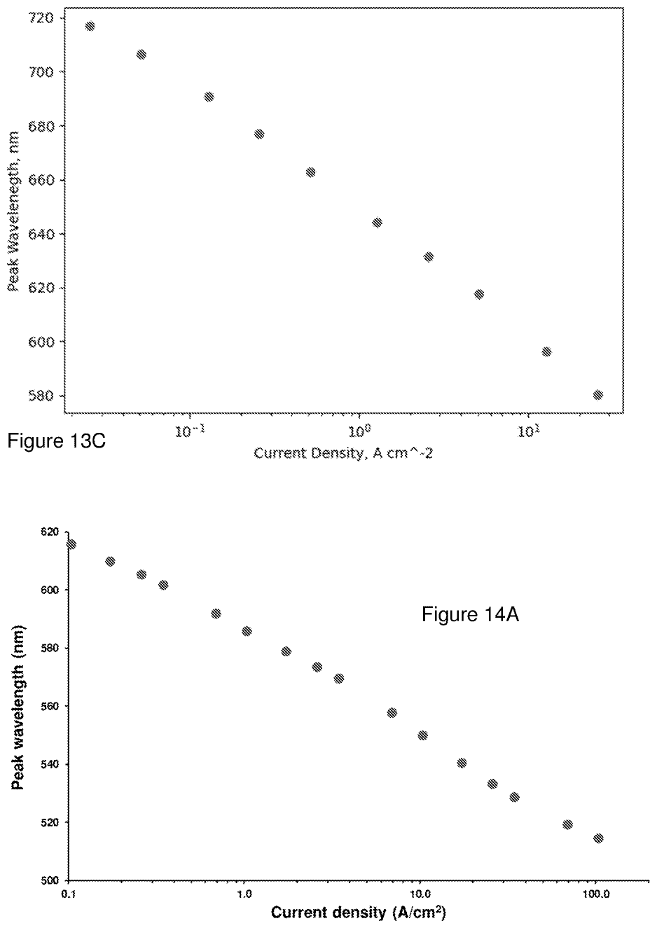

FIG. 13A is a graph of peak emission wavelength vs driving current density for a conventional non-variable wavelength LED. By varying the driving current density applied to the LED, the emission wavelength can be slightly varied, across an emission wavelength range of around 15 nm.

FIG. 13B is a graph of peak emission wavelength vs driving current density for a variable-wavelength LED usable as a first or second semiconductor device in embodiments of the present invention. In the variable-wavelength LED, varying the current density of the driving power supply creates a much larger variation in the peak emission wavelengths (WLP) emitted by the LED. In this embodiment, varying the driving current density between roughly 0.1 and 100 A/cm² varies the peak emission wavelength from around 635 nm to around 550 nm—an emission wavelength range of around 85 nm.

FIG. 13C is a graph of peak emission wavelength vs driving current density for a variable-wavelength LED according to another embodiment of the present invention. In this embodiment, varying the driving current density varies the peak emission wavelength from around 720 nm to around 580 nm—an emission wavelength range of around 140 nm.

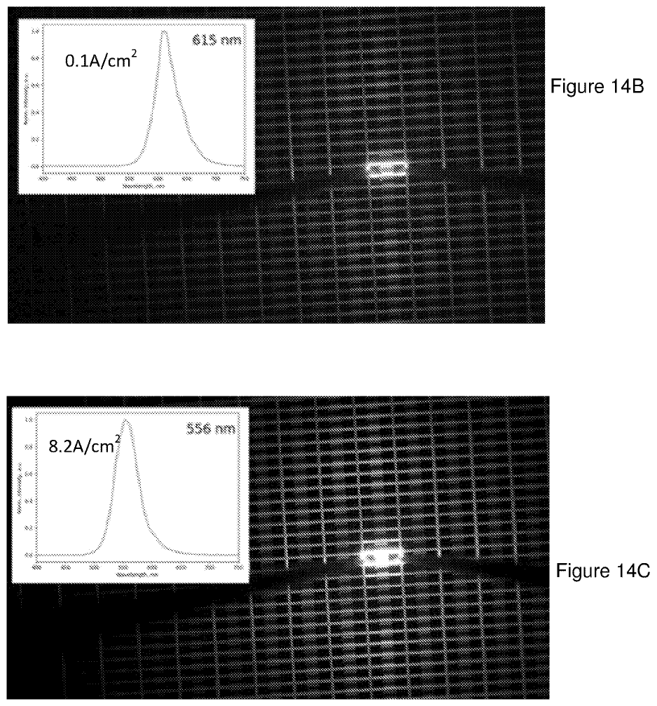

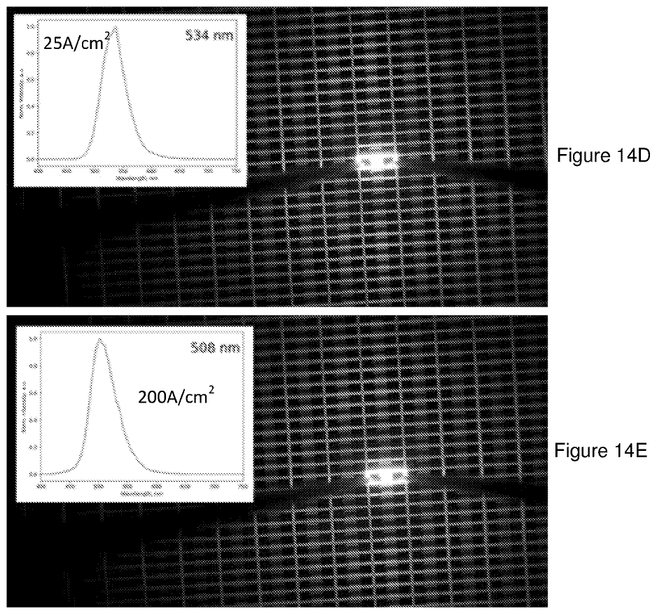

FIG. 14A is a graph of peak emission wavelength vs driving current density for another variable-wavelength LED according to the present invention. In this embodiment, varying the driving current density between roughly 0.1 and 200 A/cm² varies the peak emission wavelength from 615 nm to 508 nm—an emission wavelength range of around 100 nm. The data for this graph only goes to 514.5 nm due to a limitation on the testing capabilities. The current density for 508 nm is therefore estimated. However, the obtainable range of emission wavelengths can be pushed either way significantly.

FIGS. 14B-D are photographs of the variable-wavelength LED of FIG. 14A, showing the same variable-wavelength LED emitting at four different wavelengths across its emission wavelength range. The inset emission spectra show the different peak emission wavelengths at different driving current densities. This shows the same variable-wavelength LED emitting at peak emission wavelengths in the orange (615 nm), yellow (556 nm), green (534 nm) and blue (508 nm) in response to different driving current densities.

### PREFERRED ASPECTS

Preferred aspects of the invention are set out in the following numbered clauses:
1. A method of driving a display device comprising a variable-wavelength LED, the variable-wavelength LED being driveable to emit light at N emission wavelengths within an emission wavelength range of the variable-wavelength LED in response to N respective subfields of driving conditions, the method comprising the steps of: driving the variable-wavelength LED with a first subfield of driving conditions for a first duty cycle to emit a first primary emission wavelength λ_{P1} of the device, with a first luminance L₁;
   driving the variable-wavelength LED, or a separate LED subpixel of the display device, with a second subfield of driving conditions for a second duty cycle to emit a second primary emission wavelength λ_{P2} of the device, with a second luminance L₂, so that the light emitted at the first and second primary emission wavelengths combines to form an output signal with an output chromaticity and output luminance L_{O};
   adjusting the first subfield of driving conditions to adjust the wavelength of the first primary emission wavelength λ_{P1} to an adjusted first primary wavelength λ_{P1}′, so that driving the variable-wavelength LED to emit the adjusted first primary wavelength λ_{P1}′ for the first duty cycle results in an adjusted first luminance L₁′; and
   adjusting the second duty cycle to control the second luminance L₂, to maintain the white-balance of the output signal.
2. The method of clause 1, in which maintaining the white balance of the output signal comprises controlling the luminances of the first and second primary emission wavelengths λ_{P1}, λ_{P2}, so that the combined wavelengths and luminances are complementary and sum to a standard illuminant white point.
3. The method of clause 2, in which the standard illuminant point is CIE standard illuminant point D65.
4. The method of any preceding clause, in which the second duty cycle is adjusted to control the second luminance L₂ without adjusting the second primary emission wavelength λ_{P2}.
5. The method of any preceding clause, in which the method is a method of adjusting brightness and colour saturation in a display device comprising a variable-wavelength LED.
6. The method of any preceding clause, comprising the step of driving the display device to emit light at a set of two primary emission wavelengths, so that the output signal is a combination of light emitted at the first and second primary emission wavelengths λ_{P1}, λ_{P2}.
7. The method of clause 6, comprising the step of selecting the set of two primary wavelengths for each display frame.
8. The method of any of clauses 1 to 5, comprising the step of driving the display device to emit light at a set of three primary emission wavelengths, so that the output signal is a combination of light emitted at three discrete primary emission wavelengths: the first and second primary emission wavelengths λ_{P1}, λ_{P2}, and a third primary emission wavelength λ_{P3}.
9. The method of clause 8, comprising a step of selecting the set of three primary wavelengths for each display frame.
10. The method of any preceding clause, comprising a step of selecting different sets of primary wavelengths for emission in different display frames.
11. The method of any preceding clause, in which the first primary emission wavelength λ_{P1} is the longest of the primary emission wavelengths λ_{P} of the device.
12. The method of any preceding clause, in which the second primary emission wavelength λ_{P2} is shorter than the first primary emission wavelength λ_{P1}, and the second duty cycle is shorter than the first duty cycle.
13. The method of any preceding clause, comprising the step of, when the output luminance L_{O} is below a threshold minimum luminance, shortening the wavelength of the first primary emission wavelength λ_{P1} to increase the first luminance L₁, and increasing the second duty cycle to increase the second luminance L₂ of the second primary emission wavelength and maintain the white-balance of the output.
14. The method of any preceding clause, comprising the step of, when the output luminance L_{O} is below a threshold luminance, increasing the output luminance L_{O} by shortening the wavelength of the first primary emission wavelength λ_{P1} so that λ_{P1}′<λ_{P1} and the first duty cycle produces an increased first luminance such that L₁′>L₁, in which the step of adjusting the second duty cycle comprises increasing the second duty cycle to increase the second luminance L₂.
15. The method of any preceding clause, comprising the step of shortening the wavelength of the first primary emission wavelength λ_{P1} by between 10 nm and 65 nm, or between 20 nm and 50 nm.
16. The method of any preceding clause, in which the step of adjusting the second duty cycle comprises increasing the second duty cycle by between 10% and 95%.
17. The method of any of clauses 1 to 12, comprising the step of, in response to an input signal, lengthening the wavelength of the first primary emission wavelength λ_{P1} so that λ_{P1}′>λ_{P1} and the first duty cycle produces a reduced first luminance such that L₁′<L₁, in which the step of adjusting the second duty cycle comprises shortening the second duty cycle to reduce the second luminance L₂.
18. The method of clause 17, in which the input signal is a signal to reduce output luminance L_{O} to increase the displayable color gamut.
19. The method of any preceding clause, in which the variable-wavelength LED is configured to emit only the first primary emission wavelength λ_{P1}, in which the second primary wavelength λ_{P2} is provided by driving a second LED subpixel with the second subfield of driving conditions.
20. The method of any of clauses 1 to 18, in which the variable-wavelength LED is configured to emit two primary emission wavelengths within the emission range of the variable-wavelength LED, and the method comprises driving the variable-wavelength LED in a field-sequential manner, in which the first and second subfields of driving conditions are supplied to the variable-wavelength LED in discrete sequential subframes of a display frame, so that the variable-wavelength LED emits the first primary emission wavelength λ_{P1} and the second primary emission wavelength λ_{P2} in respective subframes.
21. The method of any preceding clause, comprising the step of driving the variable-wavelength LED, or a separate LED subpixel of the display device, with a third subfield of driving conditions for a third duty cycle to emit a third primary emission wavelength λ_{P3} of the device, with a third luminance L₃, so that the light emitted at the first, second and third primary emission wavelengths combines to form an output with an output chromaticity and output luminance L_{O};
   adjusting the first subfield of driving conditions to adjust the wavelength of the first primary emission wavelength λ_{P1} to an adjusted first primary wavelength λ_{P1}′, so that driving the variable-wavelength LED to emit the adjusted first primary wavelength λ_{P1}′ for the first duty cycle results in an adjusted first luminance L₁′; and
   adjusting the second and third duty cycles to control the second and third luminances L₂, L₃, to maintain the white balance of the combined output.
22. The method of clause 21, in which the third primary emission wavelength λ_{P3} is shorter than the first primary emission wavelength λ_{P1} and the third duty cycle being shorter than the first duty cycle.
23. The method of clause 21 or 22, comprising the step of, when the output luminance L_{O} is below a threshold luminance, increasing the output luminance L_{O} by shortening the wavelength of the first primary emission wavelength λ_{P1} so that λ_{P1}′<λ_{P1} and the first duty cycle produces an increased first luminance such that L₁′>L₁, in which the step of adjusting the second and third duty cycles comprises lengthening the second and third duty cycles to increase the second luminance L₂ and the third luminance L₃.
24. The method of clause 21 or 22, comprising the step of, in response to an input signal, lengthening the wavelength of the first primary emission wavelength λ_{P1} so that λ_{P1}′>λ_{P1} and the first duty cycle produces a reduced first luminance such that L₁′<L₁, in which the step of adjusting the second and third duty cycles comprises shortening the second and third duty cycles to reduce the second luminance L₂ and the third luminance L₃.
25. The method of clause 24, in which the input signal is a signal to reduce output luminance L_{O} to increase the displayable color gamut.
26. The method of any of clauses 21 to 25, in which the variable-wavelength LED is configured to emit only the first primary emission wavelength λ_{P1}, in which the second and third primary wavelengths λ_{P2}, λ_{P3} are provided by driving a second variable-wavelength LED subpixel, or in which the second primary wavelength λ_{P2} is provided by driving a second LED subpixel and the third primary wavelength λ_{P3} is provided by driving a third LED subpixel.
27. The method of any preceding clause, in which In which the second primary wavelength λ_{P2} is provided by driving a second subpixel.
28. The method of any preceding clause, in which the variable-wavelength LED is configured to emit three primary emission wavelengths within the emission range of the variable-wavelength LED, and the method comprises driving the variable-wavelength LED in a field-sequential manner, in which the first, second and third subfields of driving conditions are supplied to the variable-wavelength LED in discrete sequential subframes of a display frame, so that the variable-wavelength LED emits the first primary emission wavelength λ_{P1}, the second primary emission wavelength λ_{P2}, and the third primary emission wavelength λ_{P3} in respective subframes.
29. The method of any preceding clause, in which the first duty cycle is a 100% duty cycle, such that the variable-wavelength LED is driven with the first subfield of driving conditions for the entire duration of a reference display frame or display subframe.
30. The method of any preceding clause, in which the first duty cycle is not varied when the wavelength of the first primary emission wavelength λ_{P1} is varied
31. The method of any preceding clause, in which the first duty cycle is a 100% duty cycle.
32. The method of any preceding clause, in which the first primary emission wavelength λ_{P1} is a red (R) wavelength.
33. The method of any preceding clause, in which the first primary emission wavelength λ_{P1} and the adjusted first primary emission wavelength λ_{P1}′ are between 575 nm and 700 nm, or between 610 nm and 680 nm, preferably between 625 nm and 670 nm.
34. The method of any preceding clause, in which the variable-wavelength LED has an emission wavelength range with a width of between 100 nm and 200 nm, or between 125 nm and 185 nm, or between 150 nm and 175 nm.
35. The method of any preceding clause, in which the emission wavelength range extends from a lower limit, which is preferably below 500 nm or below 450 nm, to an upper limit, which is preferably above 595 nm or above 630 nm.
36. The method of clause 35, in which the lower limit of the emission wavelength range is between 440 nm and 495 nm, or between 440 nm and 485 nm, preferably between 450 nm and 470 nm.
37. The method of clause 35 or 36, in which the upper limit of the emission wavelength range is between 595 nm and 700 nm, or between 610 nm and 680 nm, preferably between 625 nm and 670 nm.
38. The method of any preceding clause, in which the variable-wavelength LED has a FWHM of 50 nm or less, or 40 nm or less, or 30 nm or less, or 20 nm or less.
39. The method of any preceding clause, comprising the step of selecting first, second and third primary emission wavelengths.
40. The method of clause 39, in which the first, second and third primary emission wavelengths are selected to be red (R), green (G) and blue (B) primary emission wavelengths respectively, and in which the three corresponding driving subfields are such driving conditions as drive the variable-wavelength LED to emit R, G and B respectively.
41. The method of clause 40, in which the variable-wavelength LED emits red light in response to the first driving subfield, green light in response to the second driving subfield, and blue light in response to the third driving subfield.
42. The method of any preceding clause, in which the variable-wavelength LED is a device pixel, and in which the method is a field-sequential driving method for driving the variable-wavelength LED pixel to emit a plurality of primary emission wavelengths in sequential subframes of a display frame.
43. The method of any preceding clause, in which the first subfield drives the variable-wavelength LED to emit a red primary emission wavelength, and in which the first duty cycle has a duration of 100% of the duration of a display subframe, so that the first luminance L₁ is the luminance emitted at the red primary emission wavelength at 100% duty cycle.
44. The method of any preceding clause, in which the method comprises the step of shortening the duty cycles of the green and blue subfields until the second and third luminances L₂, L₃ of the green and blue primary emission wavelengths fulfil a white-balance colour-mixing ratio with the red first luminance L₁.
45. The method of any preceding clause, in which the display device is a field-sequential display, and in which the driving method is a field-sequential driving method for driving a display device.
46. The method of any preceding clause, in which the variable-wavelength LED is driven using field-sequential control to emit a plurality of discrete primary emission wavelengths in respective sequential subframes of a display frame.
47. The method of any of clauses 1 to 44, in which the display device is a subpixellated display device in which the variable-wavelength LED forms a subpixel configured to emit the first primary emission wavelength, and in which the device comprises one or more additional subpixels configured to emit other primary emission wavelengths.
48. The method of any preceding clause, in which the display device comprises an array of variable-wavelength LEDs, each variable-wavelength LED in the array being individually driveable as defined in any preceding clause.
49. A method of driving a display device comprising a variable-wavelength LED, the variable-wavelength LED being driveable to emit light at emission wavelengths within an emission wavelength range of the variable-wavelength LED in response to variations in electrical driving conditions supplied to the variable-wavelength LED, the method comprising the steps of:
   adjusting the wavelength of a first primary of a set of two or more primaries, each primary having an associated wavelength and luminance, and
   adjusting the luminance of the other primaries in the set of two or more primary wavelengths to maintain a white-balance condition with the adjusted first primary.
50. The method of clause 49, in which the step of adjusting the wavelength of the first primary comprises adjusting the duty cycle of electrical driving conditions supplied to drive the first primary.
51. The method of clause 49 or 50, in which the step of adjusting the luminance of the other primaries comprises adjusting the duty cycle of electrical driving conditions supplied to drive the other primaries.

1. A method of driving a display device comprising a variable-wavelength LED, the variable-wavelength LED being a pixel of the device, or one of a plurality of subpixels of a device pixel, the display device being programmed to operate using a palette of N available primary emission wavelengths λ_{P}, wherein each of the N available primaries is a wavelength emittable by the variable-wavelength LED, the variable-wavelength LED being driveable to emit light at any of the N available primary emission wavelengths within an emission wavelength range of the variable-wavelength LED in response to N respective subfields of driving conditions, the method comprising the steps of:
identifying an output signal to be displayed by a pixel, or a subpixel, of the display device, the output signal having an output chromaticity and output luminance L_{O};
selecting a set of the N available primary emission wavelengths which are combinable to form the output signal, the set of selected primary emission wavelengths comprising a longest primary emission wavelength and one or more shorter primary emission wavelengths having wavelengths shorter than the longest primary emission wavelength, and each of the selected primary emission wavelengths being driven by a subfield of driving conditions with a respective duty cycle;
in response to an image-adjustment signal, altering the wavelength of the longest selected primary emission wavelength, and altering the duty cycles of the driving conditions which drive the shorter primary emission wavelengths; and
driving the variable-wavelength LED and optionally one or more separate LED subpixels of the display device to emit the selected primary emission wavelengths, so that the light emitted at the selected primary emission wavelengths forms an adjusted output signal.

2. The method of claim 1, in which the step of altering the wavelength of the longest primary emission wavelength comprises replacing the longest primary emission wavelength with an alternative primary emission wavelength from the palette of N available primary emission wavelengths.

3. The method of claim 1 or 2, in which, following the step of altering the wavelength of the longest primary emission wavelength and altering the duty cycles of the driving conditions driving the shorter primary emission wavelengths, the light emitted at the adjusted primary emission wavelengths forms an output signal with an adjusted output chromaticity and an adjusted output luminance L_{O}.

4. The method of claim 1, 2 or 3, in which in response to an image-adjustment signal requesting increased luminance, adjusting the set of selected primary emission wavelengths by decreasing the wavelength of the longest primary emission wavelength, and increasing the duty cycles of the driving conditions driving the shorter primary emission wavelengths.

5. The method of claim 4, in which the wavelength of the longest primary emission wavelength is decreased by replacing the longest primary emission wavelength with a shorter-wavelength primary emission wavelength from the palette of N available primary emission wavelengths.

6. The method of claim 1, 2 or 3, in which in response to an image-adjustment signal requesting reduced luminance, adjusting the set of selected primary emission wavelengths by increasing the wavelength of the longest primary emission wavelength, and decreasing the duty cycles of the driving conditions driving the shorter primary emission wavelengths.

7. The method of claim 6, in which the wavelength of the longest primary emission wavelength is increased by replacing the longest primary emission wavelength with a longer-wavelength primary emission wavelength from the palette of N available primary emission wavelengths.

8. The method of any preceding claim, in which the N available primary emission wavelengths define a colour gamut of a plurality of displayable colours, and in which the selected primary emission wavelengths define a displayable area of the colour gamut which is displayable by mixing the selected primary emission wavelengths.

9. The method of any preceding claim, in which the selected primary emission wavelengths define a displayable area of the colour gamut, and in which the step of altering the wavelength of the longest primary emission wavelength adjusts the displayable area of the colour gamut to an adjusted displayable area of the colour gamut.

10. The method of claim 9, in which the image-adjustment-signal is a luminance-adjustment signal instructing the device to adjust the output luminance L_{O} to reach an adjusted output luminance L_{O}′.

11. The method of claim 10, in which the output chromaticity is inside the displayable area of the colour gamut, but the step of altering the wavelength of the longest primary emission wavelength means that the output chromaticity is outside the adjusted displayable area of the colour gamut, wherein the method comprises the step of adjusting the output chromaticity of the output signal to an adjusted output chromaticity which is inside the adjusted displayable area of the colour gamut.

12. The method of claim 10 or 11, comprising the step of decreasing the displayable area of the colour gamut in order to reach the adjusted output luminance L_{O}″.

13. The method of any of claims 1 to 9, in which the image-adjustment-signal is a gamut-adjustment signal instructing the device to adjust the output chromaticity to reach an adjusted output chromaticity.

14. The method of claim 13, in which in response to an image-adjustment signal requesting an increase in the displayable area of the colour gamut, adjusting the set of selected primary emission wavelengths by increasing the wavelength of the longest primary emission wavelength, and decreasing the duty cycles of the driving conditions driving the shorter primary emission wavelengths.

15. The method of claim 13 or 14, in which the adjusted output chromaticity is outside the displayable area of the colour gamut, and the method comprises altering the wavelength of the longest primary emission wavelength so that the adjusted output chromaticity is inside the adjusted displayable area of the colour gamut.

16. The method of claim 13, 14 or 15, comprising the step of decreasing the output luminance L_{O} in order to increase the displayable area of the colour gamut.

17. The method of any preceding claim, comprising the step of altering the duty cycles of the driving conditions driving the shorter primary emission wavelengths to maintain a white-balance condition with the altered wavelength of the longest primary emission wavelength.

18. The method of claim 17, in which maintaining the white balance-condition of the output signal comprises controlling the luminances of the shorter primary emission wavelengths, so that the combined wavelengths and luminances of the selected primary emission wavelengths are complementary and sum to a standard illuminant white point.

19. The method of claim 18, in which the standard illuminant point is CIE standard illuminant point D65.

20. The method of any preceding claim, in which the variable-wavelength LED is a pixel of the display device, and in which the method comprise driving the variable-wavelength LED to emit the selected primary emission wavelengths in sequential subframes within a display frame.

21. The method of any of claims 1 to 19, in which the variable-wavelength LED is a device subpixel which is driven to emit the longest primary emission wavelength, and in which the one or more shorter primary emission wavelengths are provided by driving a second LED subpixel.

22. The method of any preceding claim, in which the selected primary emission wavelengths are varied between display frames, the selected primary emission wavelengths being variable within the palette of N available primary emission wavelengths.

23. The method of any preceding claim, comprising the step of selecting a pair of two primary emission wavelengths from the N available primary emission wavelengths, and driving the display device to emit light at the set of two selected primary emission wavelengths, so that the output signal is a combination of light emitted at the two selected primary emission wavelengths.

24. The method of claim 23, comprising the step of selecting a set of two primary emission wavelengths for each display frame, the two selected primary emission wavelengths being combinable to display the output signal for each respective display frame.

25. The method of any of claims 1 to 22, comprising the step of selecting a set of three primary emission wavelengths from the N available primary emission wavelengths, and driving the display device to emit light at the three selected primary emission wavelengths, so that the output signal is a combination of light emitted at the three selected primary emission wavelengths.

26. The method of claim 25, comprising a step of selecting a set of three primary wavelengths for each display frame, the three selected primary emission wavelengths being combinable to display the output signal for each respective display frame.

27. The method of any preceding claim, in which the step of identifying the output signal to be displayed comprises receiving a signal indicating the output chromaticity and output luminance which is to be displayed by the pixel or subpixel during a display frame.

28. The method of any preceding claim, in which the step of selecting a set of the N available primary emission wavelengths which are combinable to form the output signal comprises consulting a database.

29. The method of any preceding claim, in which the method is a method of adjusting brightness and colour saturation in a display device comprising a variable-wavelength LED.

30. The method of any preceding claim, comprising the step of shortening the wavelength of the longest primary emission wavelength by between 10 nm and 65 nm, or between 20 nm and 50 nm.

31. The method of any preceding claim, in which the step of adjusting the duty cycles of the one or more shorter primary emission wavelengths comprises increasing the duty cycles by between 10% and 95%.

32. The method of any preceding claim, in which the duty cycle which drives the longest primary emission wavelength is not adjusted when the wavelength of the longest primary emission wavelength is adjusted.

33. The method of any preceding claim, in which the longest primary emission wavelength is driven with a 100% duty cycle.

34. The method of any preceding claim, in which the display device is a field-sequential display, and in which the driving method is a field-sequential driving method for driving a display device.

35. The method of any preceding claim, in which the variable-wavelength LED is driven using field-sequential control to emit a plurality of selected primary emission wavelengths in respective sequential subframes of a display frame.

36. The method of any preceding claim, in which the display device comprises an array of variable-wavelength LEDs, each variable-wavelength LED in the array being individually driveable as defined in any preceding claim.

37. The method of any preceding claim, comprising the steps of:
driving the variable-wavelength LED with a first subfield of driving conditions for a first duty cycle to emit a first primary emission wavelength λ_{P1} of the device, with a first luminance L₁;
driving the variable-wavelength LED, or a separate LED subpixel of the display device, with a second subfield of driving conditions for a second duty cycle to emit a second primary emission wavelength λ_{P2} of the device, with a second luminance L₂, so that the light emitted at the first and second primary emission wavelengths forms an output signal with an output chromaticity and output luminance L_{O}, the output signal fulfilling a white-balance condition;
adjusting the first subfield of driving conditions to adjust the wavelength of the first primary emission wavelength λ_{P1} to an adjusted first primary wavelength λ_{P1}′, so that driving the variable-wavelength LED to emit the adjusted first primary wavelength λ_{P1}′ for the first duty cycle results in an adjusted first luminance L₁′; and
adjusting the second duty cycle to control the second luminance L₂, to maintain the white-balance condition of the output signal.

38. The method of claim 37, in which maintaining the white balance of the output signal comprises controlling the luminances of the first and second primary emission wavelengths λ_{P1}, λ_{P2}, so that the combined wavelengths and luminances are complementary and sum to a standard illuminant white point, preferably CIE standard illuminant point D65.

39. The method of claim 37 or 38, in which the second duty cycle is adjusted to control the second luminance L₂ without adjusting the second primary emission wavelength λ_{P2}.

40. The method of any of claims 37 to 39, in which the first primary emission wavelength λ_{P1} is the longest of the primary emission wavelengths λ_{P} of the device.

41. The method of any of claims 37 to 40, in which the second primary emission wavelength λ_{P2} is shorter than the first primary emission wavelength λ_{P1}, and the second duty cycle is shorter than the first duty cycle.

42. The method of any of claims 37 to 41, comprising the step of, when the output luminance L_{O} is below a threshold minimum luminance, shortening the wavelength of the first primary emission wavelength λ_{P1} to increase the first luminance L₁, and increasing the second duty cycle to increase the second luminance L₂ of the second primary emission wavelength and maintain the white-balance of the output.

43. The method of any of claims 37 to 42, comprising the step of, when the output luminance L_{O} is below a threshold luminance, increasing the output luminance L_{O} by shortening the wavelength of the first primary emission wavelength λ_{P1} so that λ_{P1}′<λ_{P1} and the first duty cycle produces an increased first luminance such that L₁′>L₁, in which the step of adjusting the second duty cycle comprises increasing the second duty cycle to increase the second luminance L₂.

44. The method of any of claims 37 to 41, comprising the step of, in response to an input signal, lengthening the wavelength of the first primary emission wavelength λ_{P1} so that λ_{P1}′>λ_{P1} and the first duty cycle produces a reduced first luminance such that L₁′<L₁, in which the step of adjusting the second duty cycle comprises shortening the second duty cycle to reduce the second luminance L₂.

45. The method of claim 44, in which the input signal is a signal to reduce output luminance L_{O} to increase the displayable are of the color gamut.

46. The method of any of claims 37 to 45, in which the variable-wavelength LED is configured to emit only the first primary emission wavelength λ_{P1}, in which the second primary wavelength λ_{P2} is provided by driving a second LED subpixel with the second subfield of driving conditions.

47. The method of any of claims 37 to 45, in which the variable-wavelength LED is a device pixel which is configured to emit a set of two primary emission wavelengths within the emission range of the variable-wavelength LED, and the method comprises driving the variable-wavelength LED in a field-sequential manner, in which the first and second subfields of driving conditions are supplied to the variable-wavelength LED in discrete sequential subframes of a display frame, so that the variable-wavelength LED emits the first primary emission wavelength λ_{P1} and the second primary emission wavelength λ_{P2} in respective subframes.

48. The method of any of claims 37 to 47, comprising the step of driving the variable-wavelength LED, or a separate LED subpixel of the display device, with a third subfield of driving conditions for a third duty cycle to emit a third primary emission wavelength λ_{P3} of the device, with a third luminance L₃, so that the light emitted at the first, second and third primary emission wavelengths combines to form an output with an output chromaticity and output luminance L_{O};
adjusting the first subfield of driving conditions to adjust the wavelength of the first primary emission wavelength λ_{P1} to an adjusted first primary wavelength λ_{P1}′, so that driving the variable-wavelength LED to emit the adjusted first primary wavelength λ_{P1}′ for the first duty cycle results in an adjusted first luminance L₁′; and
adjusting the second and third duty cycles to control the second and third luminances L₂, L₃, to maintain the white balance of the combined output.

49. The method of claim 48, in which the third primary emission wavelength λ_{P3} is shorter than the first primary emission wavelength λ_{P1} and the third duty cycle being shorter than the first duty cycle.

50. The method of claim 48 or 49, comprising the step of, when the output luminance L_{O} is below a threshold luminance, increasing the output luminance L_{O} by shortening the wavelength of the first primary emission wavelength λ_{P1} so that λ_{P1}′<λ_{P1} and the first duty cycle produces an increased first luminance such that L₁′>L₁, in which the step of adjusting the second and third duty cycles comprises lengthening the second and third duty cycles to increase the second luminance L₂ and the third luminance L₃.

51. The method of claim 48 or 49, comprising the step of, in response to an input signal, lengthening the wavelength of the first primary emission wavelength λ_{P1} so that λ_{P1}′>λ_{P1} and the first duty cycle produces a reduced first luminance such that L′<L₁, in which the step of adjusting the second and third duty cycles comprises shortening the second and third duty cycles to reduce the second luminance L₂ and the third luminance L₃.

52. The method of claim 51, in which the input signal is a signal to reduce output luminance L_{O} to increase the displayable area of the color gamut.

53. The method of any of claims 48 to 52, in which the variable-wavelength LED is configured to emit only the first primary emission wavelength λ_{P1}, in which the second and third primary wavelengths λ_{P2}, λ_{P3} are provided by driving a second variable-wavelength LED subpixel, or in which the second primary wavelength λ_{P2} is provided by driving a second LED subpixel and the third primary wavelength λ_{P3} is provided by driving a third LED subpixel.

54. The method of any of claims 37 to 53, in which the variable-wavelength LED is configured to emit three primary emission wavelengths within the emission range of the variable-wavelength LED, and the method comprises driving the variable-wavelength LED in a field-sequential manner, in which the first, second and third subfields of driving conditions are supplied to the variable-wavelength LED in discrete sequential subframes of a display frame, so that the variable-wavelength LED emits the first primary emission wavelength λ_{P1}, the second primary emission wavelength λ_{P2}, and the third primary emission wavelength λ_{P3} in respective subframes.

55. The method of any preceding claim, in which the variable-wavelength LED has a FWHM of 50 nm or less, or 40 nm or less, or 30 nm or less, or 20 nm or less.

56. The method of any preceding claim, comprising the step of selecting first, second and third primary emission wavelengths which are red (R), green (G) and blue (B) primary emission wavelengths respectively, and in which the three corresponding driving subfields are such driving conditions as drive the variable-wavelength LED to emit R, G and B respectively.

57. The method of claim 56, in which the variable-wavelength LED emits red light in response to the first driving subfield, green light in response to the second driving subfield, and blue light in response to the third driving subfield.

58. The method of any preceding claim, in which the variable-wavelength LED is a device pixel, and in which the method is a field-sequential driving method for driving the variable-wavelength LED pixel to emit a plurality of primary emission wavelengths in sequential subframes of a display frame.

59. A method of driving a display device comprising a variable-wavelength LED, the variable-wavelength LED being driveable to emit light at emission wavelengths within an emission wavelength range of the variable-wavelength LED in response to discrete electrical driving conditions supplied to the variable-wavelength LED, the method comprising the steps of:
adjusting the wavelength of a first primary of a set of two or more primaries, each primary having an associated wavelength and luminance, and
adjusting the luminance of the other primaries in the set of two or more primary wavelengths to maintain a white-balance condition with the adjusted first primary.

60. The method of claim 59, in which the step of adjusting the wavelength of the first primary comprises adjusting the duty cycle of electrical driving conditions supplied to drive the first primary.

61. The method of claim 59 or 60, in which the step of adjusting the luminance of the other primaries comprises adjusting the duty cycle of electrical driving conditions supplied to drive the other primaries.
